(19) United States
(12) Patent Application Publication
(10) Pub. No.: US 2007/0063226 A1
(43) Pub. Date: Mar. 22, 2007

(54) Laser irradiation apparatus and laser irradiation method

(75) Inventors: Koichiro Tanaka, Kanagawa (JP); Yoshiaki Yamamoto, Kanagawa (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., ATSUGI-SHI (JP)

(21) Appl. No.: 10/579,238

(22) PCT Filed: Oct. 27, 2005
(86) PCT No.: PCT/JP05/20166

§ 371 Date: May 12, 2006

(30) Foreign Application Priority Data
Oct. 29, 2004 (JP) 2003-317057

(51) Int. Cl. H01L 29/76

(52) U.S. Cl. 257/213

(57) ABSTRACT

It is an object of the present invention to provide a laser irradiation apparatus and a laser irradiation method which can conduct a laser process homogeneously to the whole surface of a semiconductor film. A laser beam oscillated from a laser crystal having a wide wavelength range and a beam homogenizer are used. Since the laser beam having a wide wavelength range has low coherency, an interference pattern does riot appear on a semiconductor film. Moreover, a linear beam having a length of several meters or more in its major axis can be formed, which increases throughput of a laser anneal process.

### TECHNICAL FIELD

The present invention relates to a laser irradiation apparatus (an apparatus including a laser and an optical system for guiding a laser beam emitted from the laser to an irradiation object) and a laser irradiation method which are for homogeneously and effectively annealing a semiconductor material or the like. Further, the present invention relates to a method for manufacturing a semiconductor device by conducting the above laser process step.

### BACKGROUND ART

In recent years, a technique to manufacture a thin film transistor (hereinafter referred to as a TFT) over a substrate has significantly progressed, and application thereof to an active matrix display device has been advanced. In particular, since a TFT using a poly-crystalline semiconductor film has higher electric-field effect mobility (also referred to as mobility simply) than a TFT using a conventional non-single crystal semiconductor film, high-speed operation is possible. Therefore, it is tried to control a pixel, which has been conventionally controlled by a driver circuit provided outside a substrate, by a driver circuit formed over the same substrate as the pixel.

A substrate used for a semiconductor device is expected to be a glass substrate rather than a single-crystal semiconductor substrate in terms of cost. However, a glass substrate is inferior in heat resistance and easily deformed due to heat. Therefore, when a semiconductor film is crystallized to form a TFT using a poly-crystalline semiconductor film over a glass substrate, laser annealing is often employed in order to prevent the glass substrate from being deformed due to the heat.

Compared with another annealing method which uses radiant heat or conductive heat, the laser annealing has advantages that a process time can be shortened drastically and that a semiconductor substrate or a semiconductor film over a substrate can be heated selectively and locally so that almost no thermal damage is given to the substrate.

Laser oscillators used for the laser annealing are categorized as pulsed laser oscillators and continuous wave laser oscillators according to the oscillation method. In the laser annealing, a pulsed laser such as an excimer laser is often used. An excimer laser has advantages of high output power, capability of irradiation with a high repetition rate, and moreover, high absorption coefficient to a silicon film which is often used as a semiconductor film. At the irradiation with a laser beam, the laser beam is shaped into a linear beam through an optical system on an irradiation surface and delivered to the irradiation surface by moving an irradiation position of the laser beam relative to the irradiation surface. Since such a method provides high productivity, this method is superior industrially (see Patent Document 1: Japanese Patent Document Laid-Open No: 2003-257885).

It is to be noted that the linear beam means a laser beam whose shape on an irradiation surface is linear. The term of linear herein used does not mean a line in a strict sense but means a rectangle having a high aspect ratio (for example, aspect ratio of 10 or more (preferably 100 or more)). The laser beam is shaped into the linear beam because energy density required for sufficiently annealing an irradiation object can be secured. When sufficient annealing can be conducted to an irradiation object, the laser beam may be shaped into a rectangular or planar beam.

In recent years, it has been known that the diameter of a crystal grain formed in a semiconductor film becomes larger when using a continuous wave laser oscillator (hereinafter referred to as a CW laser) such as an Ar laser or a YVO₄ laser or a pulsed laser oscillator having a very high repetition rate (a mode-locked pulsed laser) than when using a pulsed laser oscillator such as an excimer laser in crystallizing the semiconductor film. When the diameter of a crystal grain in a semiconductor film becomes larger, the number of crystal grain boundaries in a channel region of a TFT formed using this semiconductor film decreases and the mobility becomes higher so that a more sophisticated device can be developed (hereinafter, in this specification, a crystal having such a large grain diameter is referred to as a large grain crystal).

Wavelengths of fundamental waves emitted from solid-state lasers commonly employed in the laser annealing range from red to near-infrared. However, the absorption efficiency of energy into a semiconductor film is higher in a visible to ultraviolet wavelength range than in the red to near-infrared wavelength range. Consequently, in general, a fundamental wave where high output power is easily obtained is converted by using a non-linear optical element into a harmonic so that the laser beam becomes visible light, and the visible light is used to anneal a semiconductor film.

For example, when a laser beam emitted from a CW laser providing 10 W at 532 nm is shaped into a linear beam having a size of approximately 300 μm in a major-axis direction and approximately 10 μm in a minor-axis direction and this linear beam is moved in the minor-axis direction of the linear beam to crystallize a semiconductor film, a region including large grain crystals obtained by scanning once is approximately 200 μm in width (hereinafter the region where the large grain crystal is observed is referred to as a large grain region). That is to say, the laser annealing is conducted in the following way: a laser beam is moved in a minor-axis direction of a beam spot; an irradiation position with a laser beam is displaced in a major-axis direction of the beam spot by the width of the large grain region obtained by scanning once, specifically by a width of 200 μm in the above example; and the laser beam is moved again in the minor-axis direction of the beam spot. By alternately repeating the beam irradiation and the displacement of the irradiation position, the whole surface of the substrate is irradiated with the laser beam to crystallize the semiconductor film.

### DISCLOSURE OF INVENTION

Here, an irradiation track of a beam spot on a semiconductor film and intensity distribution of a beam spot at its cross section are shown.

In general, as shown in FIG. 24, a cross section of a laser beam emitted from a laser oscillator at a-a′ in FIG. 24 has Gaussian intensity distribution which is not homogeneous.

For example, the energy density of the beam spot in its central portion is higher than a threshold (y) at which a large grain crystal is formed. However, the energy density of the beam spot in its end portion is lower than the threshold (y) and higher than a threshold (x) at which a crystalline region is formed. Therefore, when the semiconductor film is irradiated with the laser beam, some parts of a region irradiated with the end portion of the beam spot are not melted completely. In this not-melted region, not the large grain crystal which is formed by the central portion 2401 of the beam spot but only a crystal grain having relatively small grain diameter is formed. That is to say, the crystallinity becomes uneven because the crystallinity of the surface of the semiconductor film reflects the energy density distribution of the laser beam.

In particular, in the case of conducting laser annealing after shaping a CW laser beam into a linear beam, the decrease in intensity of the CW laser beam at its opposite end portions in the major-axis direction of the linear beam has a significant impact. In a region irradiated with a CW laser beam having energy in the range of the threshold (x) to the threshold (y), a region 2402 is formed where the large grain crystal is not formed although the crystallization occurs (hereinafter this region 2402 is referred to as an inferior crystalline region). In the region 2402, the surface of the semiconductor film is uneven; therefore, the region 2402 is unsuitable for manufacturing TFTs therein.

If TFTs are formed using the semiconductor film manufactured thus, the electron mobility of the respective TFTs is difficult to be homogenized. Moreover, if an EL (electroluminescence) display or a liquid crystal display is manufactured using the TFTs manufactured thus, a stripe pattern may appear due to the uneven crystallinity.

Therefore, when manufacturing TFTs with high reliability, it is necessary to determine a position accurately in irradiating with a laser beam so that TFTs are not manufactured in the inferior crystalline region 2402.

Moreover, when the length of the linear beam in the major-axis direction is made longer, the end portion of the laser beam where the intensity is low is extended because the laser beam used in the laser annealing has Gaussian intensity distribution, which results in the expansion of the inferior crystalline region 2402. Therefore, a region where TFTs can be formed in the whole substrate becomes small and it is difficult to manufacture a highly integrated semiconductor device.

The above problem can be solved by changing the intensity distribution of the laser beam from the Gaussian shape into a shape in which the intensity is homogeneous and the end is sharp. As a means for homogenizing the intensity distribution of the laser beam, a diffractive optical element (diffractive optics), an optical waveguide (light pipe), a lens array having a plurality of lenses arranged on a plane (such as a cylindrical lens array or a fly-eye lens), or the like can be given. By homogenizing the intensity distribution of the laser beam and sharpening the end portion thereof with such a means, the crystallinity obtained after the laser annealing can be homogenized and moreover the inferior crystalline region can be decreased. By homogenizing the intensity distribution of the laser beam, the area of the inferior crystalline region can be suppressed not depending on the length of the linear beam.

However, among the introduced means for homogenizing the intensity distribution of the laser beam, the diffractive optical element has some disadvantages of its low optical transmissivity, high cost, and technical difficulty because the diffractive optical element requires fine processing with nanometer-scale accuracy to obtain a good characteristic. Moreover, in the case of using a beam homogenizer, for example a light pipe or lens array such as a cylindrical lens array or a fly-eye lens, to divide one laser beam into a plurality of paths and combine the divided laser beams into one beam again, the degree of the intensity of the laser beam appears as an interference pattern on an irradiation surface because the laser beam of a single wavelength has high coherency.

It is an object of the present invention to obtain a linear beam having homogeneous energy distribution without causing an interference pattern to appear due to laser coherency. In particular, it is an object of the present invention to increase the area of a large grain region and decrease the area of an inferior crystalline region as much as possible in the case of using a CW laser or a mode-locked pulsed laser. Meanwhile, it is an object of the present invention to form a linear beam having a length more than several meters by using a pulsed laser which provides high output power with a relatively low repetition rate to drastically increase the throughput of a laser anneal process.

As a means for solving the above problems, the present invention employs the following structure. It is to be noted that the laser annealing method herein described includes a technique for recrystallizing an amorphous layer or a damaged layer formed in a semiconductor substrate or a semiconductor film and a technique for crystallizing an amorphous semiconductor film formed over a substrate. Further, the laser annealing method includes a technique applied to flattening or modification of a surface of a semiconductor substrate or a semiconductor film, a technique for conducting laser irradiation to an amorphous semiconductor film in which a crystallization-inducing element such as nickel has been added, a technique for irradiating a semiconductor film having crystallinity with a laser, and so on.

The present invention has the following structure.

One aspect of the present invention comprises a laser oscillator having a wide oscillation wavelength range, a beam homogenizer for homogenizing intensity distribution of a laser beam emitted from the laser oscillator, and a means for moving an irradiation surface relative to the laser beam.

Another aspect of the present invention comprises a laser oscillator having a wide oscillation wavelength range, a beam homogenizer for homogenizing intensity distribution of a laser beam emitted from the laser oscillator, a condensing lens, a means for projecting an image of the condensing lens onto an irradiation surface on a transmission line of the laser beam, and a means for moving the irradiation surface relative to the laser beam.

Another aspect of the present invention comprises a laser oscillator having a wide oscillation wavelength range, a beam homogenizer for homogenizing intensity distribution of a laser beam emitted from the laser oscillator, a slit for blocking an end portion of the laser beam that has low intensity, a projecting lens for projecting an image of the slit onto an irradiation surface, a condensing lens, and a means for moving the irradiation surface relative to the laser beam.

The laser oscillator having a wide oscillation wavelength range indicates a laser oscillator capable of oscillating a laser beam with a wide range of wavelengths with respect to an excitation light source, that is, a laser oscillator which emits a laser beam having a spectral width. Concretely, the spectral width is necessary to be 0.1 nm or more.

In the above structure of the present invention, the laser oscillator may include a crystal of sapphire, YAG, ceramic YAG, ceramic Y₂O₃, KGW, KYW, Mg₂SiO₄, YLF, YVO₄, or GdVO₄ each of which is doped with one or more selected from Nd, Yb, Cr, Ti, Ho, and Er as a laser crystal having a wide oscillation wavelength range. It is preferable to use a laser crystal doped with a plurality of dopants in order to widen the oscillation wavelength range. Some lasers can oscillate multiple wavelengths with one kind of dopant like a Thsapphire laser.

From the laser crystal described above, a laser beam may be emitted with extremely high output power; therefore, the length of a linear beam for conducting laser annealing to a semiconductor film, that is, the length of a laser spot in a major-axis direction can be made several meters or more. For example, in the case of using ceramic YAG, a large ceramic can be formed by spending less manufacturing time and cost than a YAG crystal. This is similar even in the case of using other ceramics. For this reason, the length in the major-axis direction of the beam can be made longer than the other lasers at the stage of emission from the laser oscillator. Moreover, since the ceramic can change in shape freely, a square beam can be oscillated by forming a cuboid rod.

The laser beam having a wide oscillation wavelength range described above has low coherency. Therefore, an interference pattern due to the laser beam does not appear on the irradiation surface even when one laser beam is divided into a plurality of paths by using a beam homogenizer such as a cylindrical lens array, a light pipe, or a fly-eye lens and the divided beams are combined again on one position. Thus, a semiconductor film can be annealed homogeneously.

In the above structure of the present invention, since the beam homogenizer can be considered to form a beam emitted from a double slit, a period of the interference pattern formed by the beam homogenizer can be calculated by using the double slit as a model. In other words, an interval x of an interference pattern at a certain wavelength λ can be expressed as the following formula I where L is a distance from the double slit to an irradiation surface and d is a distance between adjacent slits in the double slit.

$$X = \frac{λ L}{d} - ( A ) \qquad [ formula 1 ]$$

FIG. 1 shows a calculation result of the interval x of an interference pattern with respect to the wavelength λ when the distance d between the adjacent slits in the double slit is 2 mm and the distance L from the double slit to the irradiation surface is 1,000 mm. It is understood that the interval x of the interference pattern increases linearly with respect to the wavelength λ. Therefore, since the interference pattern caused by the laser beam having a wide oscillation wavelength range is formed by mixing various standing waves, the pattern becomes so obscure that the pattern cannot be observed.

Moreover, in the above structure of the present invention, the condensing lens is one or two convex cylindrical lenses or convex spherical lenses.

By applying the present invention, a linear beam having homogeneous energy distribution which does not cause a laser interference pattern to appear on a semiconductor film can be obtained. In particular, in the case of using a CW laser or a mode-locked pulsed laser, the area of a large grain region can be increased and that of an inferior crystalline region can be decreased as much as possible. On the other hand, a linear beam having a length of several meters can be formed by using a pulsed laser providing high output power with a relatively low repetition rate, which enables the throughput of the laser annealing to increase drastically.

### BRIEF DESCRIPTION OF DRAWINGS

In the following drawings:

FIG. 1 is a graph showing a relation between a wavelength and an interval of an interference pattern;

FIG. 2 is a schematic view showing a laser irradiation apparatus of the present invention;

FIG. 3-(1) is a top view and FIG. 3-(2) is a side view both showing an optical system used in a laser irradiation apparatus of the present invention;

FIG. 4 is a schematic view showing the present invention;

FIG. 5 shows an example of a laser irradiation apparatus of the present invention;

FIGS. 6-(1) and 6-(2) show an example of an optical system used in a laser irradiation apparatus of the present invention;

FIGS. 7A to 7D are schematic views showing manufacturing steps of a TFT using laser irradiation of the present invention;

FIGS. SA to 8D are schematic views showing crystallization of a semiconductor film using laser irradiation of the present invention;

FIGS. 9A to 9C are schematic views showing crystallization of a semiconductor film using laser irradiation of the present invention;

FIG. 10 is a schematic view showing a manufacturing step of a display device using laser irradiation of the present invention;

FIG. 11 is a schematic view showing a manufacturing step of a display device using laser irradiation of the present invention;

FIGS. 12A to 12C are schematic views showing manufacturing steps of a CPU using laser irradiation of the present invention;

FIGS. 13A to 13C are schematic views showing manufacturing steps of a CPU using laser irradiation of the present invention;

FIGS. 14A to 14C are schematic views showing manufacturing steps of a CPU using laser irradiation of the present invention;

FIGS. 15A and 15B are schematic views showing manufacturing steps of a CPU using laser irradiation of the present invention;

FIG. 16 is a schematic view showing a manufacturing step of a CPU using laser irradiation of the present invention;

FIGS. 17A to 17E are schematic views showing manufacturing steps of a wireless IC tag using laser irradiation of the present invention;

FIGS. ISA to 18C are schematic views showing manufacturing steps of a wireless IC tag using laser irradiation of the present invention;

FIGS. 19A and 19B are schematic views showing manufacturing steps of a wireless IC tag using laser irradiation of the present invention;

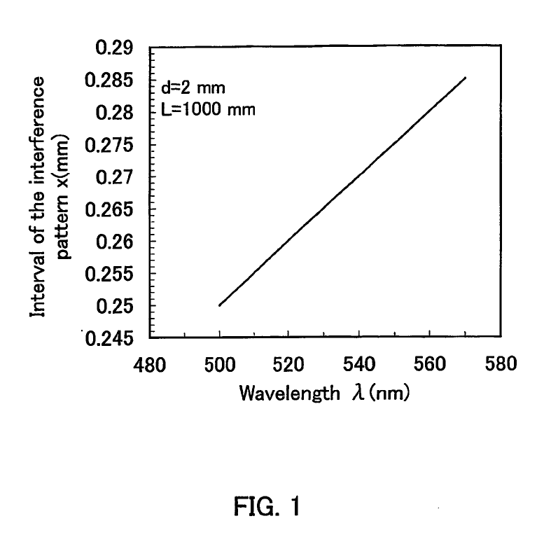

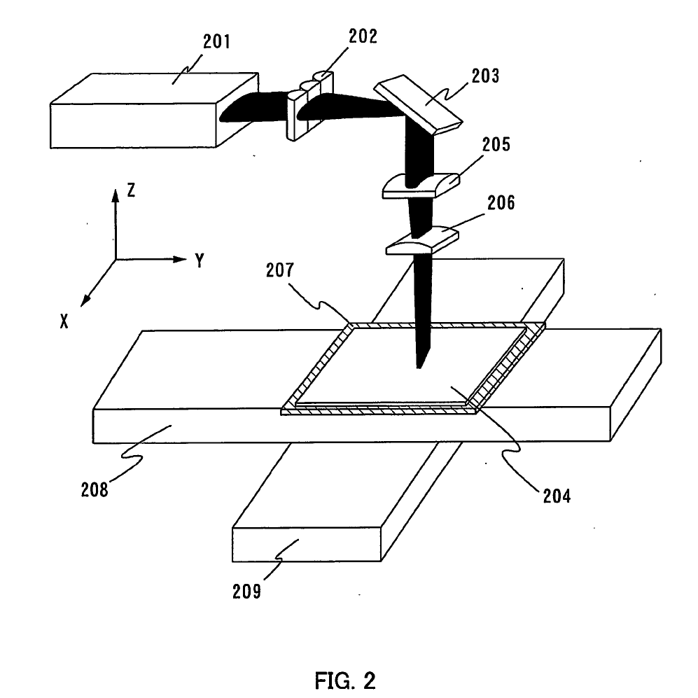

FIGS. 2OA to 2OC are schematic views showing manufacturing steps of a wireless IC tag using laser irradiation of the present invention;

FIGS. 21A and 21B are schematic views showing manufacturing steps of a wireless IC tag using laser irradiation of the present invention;

FIGS. 22A to 22F are schematic views showing electronic appliances using laser irradiation of the present invention;

FIGS. 23A and 23B are schematic views showing electronic appliances using laser irradiation of the present invention;

FIG. 24 shows energy density distribution of a laser beam;

FIG. 25 shows an example of a laser irradiation apparatus of the present invention; and

FIG. 26-(1) is a top view and FIG. 26-(2) is a side view both showing the irradiation apparatus shown in FIG. 25.

### BEST MODE FOR CARRYING OUT THE INVENTION

Embodiment Mode and Embodiments of the present invention are hereinafter described with reference to the drawings. However, since the present invention can be carried out with many different modes, it is understood by those skilled in the art that the mode and the detail can be variously changed without departing from the scope and the spirit of the present invention. Therefore, the present invention is not limited to the description of Embodiment Mode and Embodiments.

Embodiment Mode of the present invention describes an example in which a laser beam emitted from a mode-locked pulsed laser oscillator 201 which oscillates multiple wavelengths with a repetition rate of 10 MHz or more is shaped into a linear beam by an optical system and delivered to a substrate with a semiconductor film 204 formed, with reference to FIG. 2.

Although most of common lasers oscillate a single wavelength, some lasers stimulate and emit light with respect to a wide range of wavelengths. That is to say, laser beams emitted from such lasers have spectral widths. In a solid-state laser, when various energy levels are made by changing the distance between a host crystal and a light-emitting atom to change a relative positional relation, laser transition falling from an excited level to a lower level has a wide gap, thereby emitting a laser beam with a wide range of wavelengths. Moreover, when a medium is formed by introducing plural kinds of light-emitting atoms into a host crystal, various energy levels are formed, thereby emitting a laser beam with a wide range of wavelengths. By using such a medium, a laser beam can be oscillated with a wide range of wavelengths with respect to an excitation light source. In this specification, the laser oscillating multiple wavelengths indicates the above lasers. Concretely, the spectral width is necessary to be 0.1 nm or more.

In FIG. 2, the laser beam emitted from the mode-locked pulsed laser oscillator 201 is divided into a plurality of laser beams by a cylindrical lens array 202. The divided laser beams are deflected by a mirror 203 in a direction toward the substrate with the semiconductor film 204 formed.

After that, the laser beam is condensed by cylindrical lenses 205 and 206 acting in a major-axis direction and a minor-axis direction of the laser beam. In Embodiment Mode of the present invention, two cylindrical lenses are used as the condensing lens. One of the cylindrical lenses 205 and 206 is used to shape the beam in the major-axis direction of the linear beam and the other is used to shape the beam in the minor-axis direction of the linear beam.

The advantage in using the cylindrical lenses 205 and 206 is that the beam can be independently condensed in each of the major-axis direction and the minor-axis direction. If the beam diameter, output power, and beam shape of an original beam can be used without any changes, two cylindrical lenses are not necessarily used. If the beam is condensed while maintaining the ratio between the lengths of the major axis and the minor axis of the original beam, a spherical lens may be used instead of the cylindrical lenses 205 and 206.

The substrate with the semiconductor film 204 formed is made with glass and fixed to a suction stage 207 so as not to fall during the laser irradiation. The suction stage 207 repeatedly moves in an X direction and a Y direction on a plane parallel to a surface of the semiconductor film 204 with the use of an X stage 208 and a Y stage 209.

Although the substrate with the semiconductor film 204 formed is moved by using the X stage 208 and the Y stage 209 in this embodiment mode, the laser beam may be moved by any one of the following methods: (1) an irradiation system moving method in which a substrate as a process object is fixed while an irradiation position of the laser beam is moved; (2) an object moving method in which the irradiation position of the laser beam is fixed while the substrate is moved; and (3) a method in which these two methods are combined.

The irradiation region where a crystal grain has grown toward the scanning direction by being irradiated with the laser beam has very superior crystallinity. For this reason, by using this region for a channel-forming region of a TFT, extremely high mobility and on current can be expected.

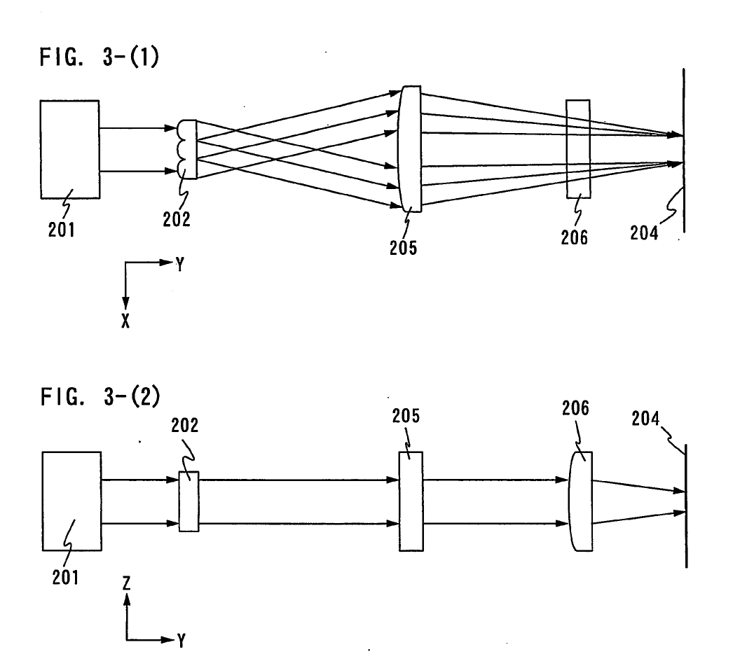

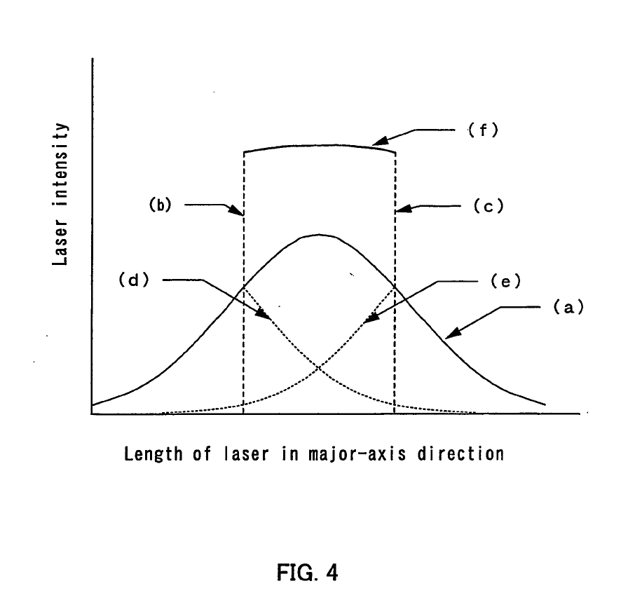

Here, an optical system of the present invention is hereinafter described in detail with reference to FIGS. 3-(1) and 3-(2) and FIG. 4. In FIGS. 3-(1) and 3-(2), the same parts as those in FIG. 2 are denoted with the same reference numerals.

FIG. 3-(1) is a top view showing a linear beam and an optical system. FIG. 3(2) is a side view showing the linear beam and the optical system. A laser beam emitted from the laser oscillator 201 is divided into a plurality of laser beams by a cylindrical lens array 202. At this time, the laser beam emitted from the laser oscillator 201 has Gaussian intensity distribution shown with a line (a) in FIG. 4. This laser beam is divided by the cylindrical lens array 202 at positions indicated with lines (b) and (c) in FIG. 4. The divided laser beams are superposed by the cylindrical lenses 205 and 206 at a position between the lines (b) and (c) as shown with lines (d) and (e) so that the beams are combined into one beam spot on the semiconductor film 204. A line (f) in FIG. 4 shows intensity distribution of the laser beam formed by adding the superposed three laser beams. This homogenizes the intensity distribution of the laser beam.

The laser crystal in the laser oscillator 201 used in this embodiment mode is a Thsapphire crystal. The central wavelength of the fundamental wave of this laser is 800 nm, and a full width at half maximum of the oscillation wavelength is 30 nm. This fundamental wavelength is converted into a second harmonic by a non-linear optical element inside the laser oscillator 201. The central wavelength of this second harmonic is 400 nm, and a full width at half maximum thereof is 15 nm.

Although the laser beam is divided into three beams and combined into one laser beam in this embodiment mode, the difference in the light intensity due to the interference of the laser beams can be offset because the interval of the interference pattern with respect to each wavelength differs as can be seen from the formula (1).

This can decrease the effect of the interference; therefore, the intensity distribution of the laser beam in a direction of the length of the linear beam can be homogenized and moreover the inferior crystalline region can be decreased.

The glass substrate with the semiconductor film 204 formed is set onto the X stage 208 and the Y stage 209 capable of moving at a speed of 100 to 1,000 mm/s and moved at appropriate speed, thereby manufacturing large grain crystals on the whole surface of the semiconductor film 204 over the substrate. According to the experiences of the present inventor, the optimum scanning speed is expected to be approximately 400 mm/s.

A high-speed device can be manufactured by manufacturing TFTs by a known means using the semiconductor film 204 where the large grain crystals are formed by such a technique.

Although this embodiment mode has described an example of manufacturing the large grain crystal using the CW laser having a wide range of oscillation wavelengths, that is, a spectral width, the present invention can also be applied to the case of conducting the laser annealing by combining the beam homogenizer and a pulsed laser having a high repetition rate and a wide oscillation wavelength range.

### Embodiment 1

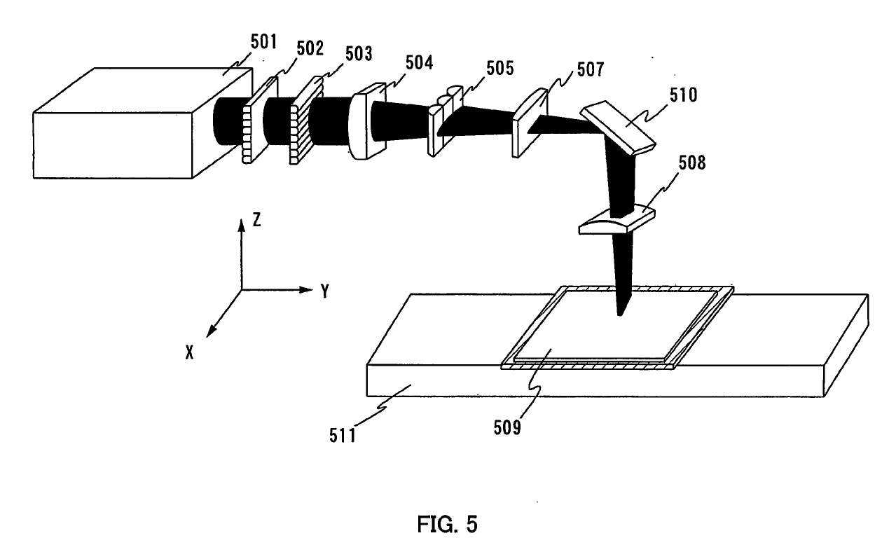

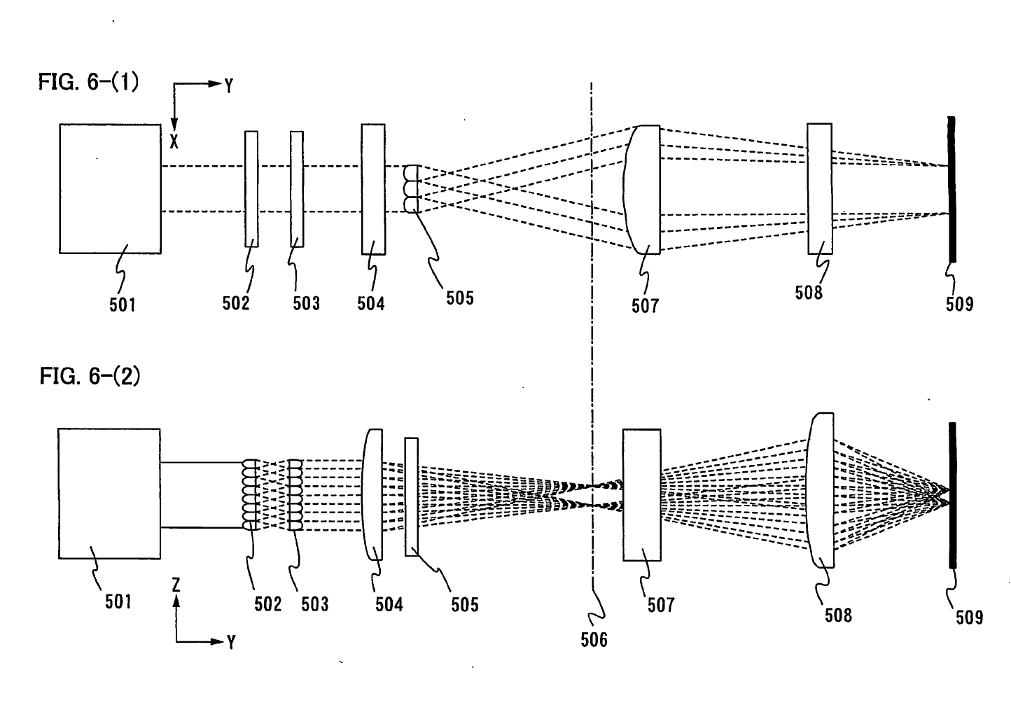

This embodiment will describe an example of using a pulsed laser which provides high energy per shot and has a low repetition rate, with reference to FIG. 5 and FIGS. 6-(1) and 6-(2).

A side view of FIG. 6-(2) is described first. A laser beam emitted from a pulsed laser oscillator 501 enters cylindrical lens arrays 502 and 503. The cylindrical lens arrays 502 and 503 divide one laser beam into a plurality of laser beams in a Z-axis direction and homogenize the intensity of the laser beam in the Z-axis direction.

Next, the laser beams divided in the Z-axis direction is condensed into one beam by a cylindrical lens 504 acting only in the Z-axis direction on a virtual plane 506. Since the plane 506 is in the middle of the optical path, the light condensed at the plane 506 diverges. It is noted that the cylindrical lens array 505 does not act in the Z-axis direction of the laser beam.

A cylindrical lens 508 is disposed so that the plane 506 and a semiconductor film 509 are in a conjugate relation. Then, the laser beams divided in the Z-axis direction are condensed again so as to form one image on the semiconductor film 509. At this time, the cylindrical lens 508 acts only in the minor-axis direction of the linear beam delivered to the semiconductor film 509.

Next, the top view (FIG. 6-(I)) is described. The laser beam emitted from the pulsed laser oscillator 501 enters the cylindrical lens arrays 502 and 503 and the cylindrical lens 504. Since the cylindrical lens arrays 502 and 503 and the cylindrical lens 504 do not act in the X-axis direction of the laser beam, the laser beam passes through the lenses without any change. Subsequently, the laser beam enters the cylindrical lens array 505 which is disposed so that the direction of its generatrix intersects with generatrices of the cylindrical lens arrays 502 and 503. With this cylindrical lens array 505, one laser beam is divided into a plurality of beams in the X-axis direction. The divided laser beams are condensed into one beam spot on the semiconductor film 509 by the cylindrical lens 507.

As shown in FIG. 5, the laser beam passed through the cylindrical lens 507 is deflected 90° downward by a mirror 510 and delivered to the semiconductor film 509. At this time, the cylindrical lens 507 acts only in the major-axis direction of the linear beam to be delivered to the semiconductor film 509.

A glass substrate with the semiconductor film 509 formed is set onto a stage 511 capable of moving at a speed of 10 mm/s or more and moved at appropriate speed, thereby crystallizing the whole surface of the substrate.

In the example shown in this embodiment, the laser beam is divided into a plurality of beams and the beams are combined into one beam; therefore, the interference pattern may appear. However, it is understood from the formula (1) that the interval of the interference pattern is different for each wavelength. For this reason, when the laser beam having a wide range of wavelengths is used, the difference in the intensity of light due to the interference can be offset and the effect of the interference can be decreased. As a result, the intensity distribution of the laser beam shaped into the linear beam can be homogenized.

A laser crystal of the laser oscillator 501 used in this embodiment is a ceramic YAG. By doping the ceramic YAG with plural dopants such as Nd and Yb, multiple wavelength oscillation is achieved. The central wavelength of the fundamental wave of this laser ranges from 1030 to 1064 nm and the full width at half maximum of the oscillation wavelength is approximately 30 nm. This fundamental wavelength is converted into a second harmonic by a non-linear optical crystal inside the laser oscillator 501. This second harmonic has a central wavelength ranging from 515 to 532 nm and a full width at half maximum of approximately 15 nm.

The ceramic YAG used as a laser crystal in this embodiment can be manufactured to be larger in a shorter time and at lower cost than a YAG crystal. Moreover, the shape of the ceramic YAG can be freely designed in accordance with the shape of the laser beam to be delivered to the semiconductor film. For this reason, the laser beam can be made longer in the major-axis direction of the beam than the other laser beams at the stage of emission from the laser oscillator.

Since the laser used in this embodiment employs a ceramic as the laser crystal, the laser crystal can be made extremely large. Therefore, the output power can be drastically increased and the area of the linear beam can be made 1 cm² or more. By shaping the beam using an optical system, a linear beam having a length of several hundred mm to several meters in the major-axis direction can be obtained. Generally, a panel size of a display manufactured through a process using a linear beam is restricted by the length of the linear beam. Therefore, by obtaining a longer linear beam according to the present invention, a larger display can be manufactured.

TFTs can be manufactured by a method shown in Embodiment 2 on the semiconductor film crystallized by such a technique. Although Embodiment 2 will show an example of crystallizing a semiconductor film by using a CW ceramic laser, the pulsed laser shown in this embodiment may be used alternatively.

This embodiment can be freely combined with another embodiment.

### Embodiment 2

This embodiment shows a step of manufacturing a thin film transistor (TFT) using a laser annealing apparatus of the present invention. Although this embodiment will describe a method for manufacturing a top-gate (staggered) TFT, the present invention can be applied to not only the top-gate TFT but also a bottom-gate (inversely staggered) TFT.

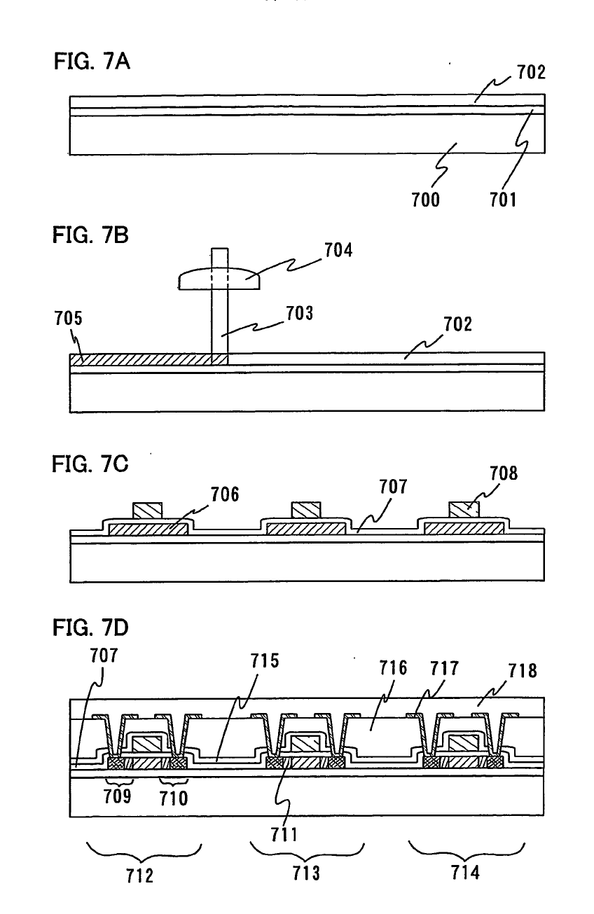

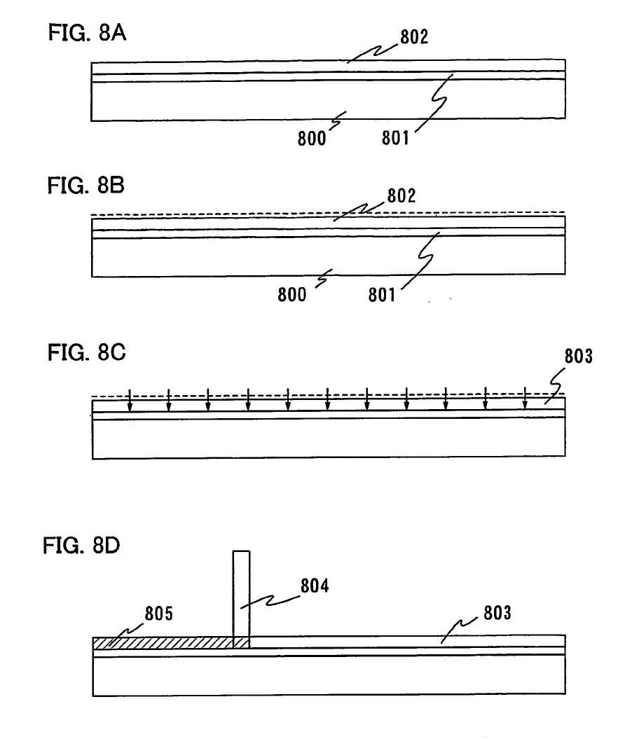

As shown in FIG. 7A, a base film 701 is formed over a substrate 700 having an insulating surface. In this embodiment, a glass substrate is used as the substrate 700. As the substrate used here, a glass substrate made of barium borosilicate glass, aluminoborosilicate glass, or the like, a quartz substrate, a ceramic substrate, a stainless steel substrate, or the like can be used. Moreover, although a substrate made of synthetic resin typified by acrylic or plastic such as PET (Polyethylene Terephthalate), PES (Polyethersulfone resin), or PEN (Polyethylene Naphthalate) tends to have lower heat resistance than the other substrates, the substrate made of synthetic resin can be used if the substrate can resist a process of this step.

The base film 701 is provided in order to prevent alkali-earth metal or alkali metal such as Na included in the substrate 700 from diffusing into a semiconductor. Alkali-earth metal or alkali metal causes an adverse effect on the characteristic of a semiconductor element when the metal is in the semiconductor. Therefore, the base film is formed with an insulating material such as silicon oxide, silicon nitride, or silicon nitride oxide, which can suppress the diffusion of alkali-earth metal and alkali metal into the semiconductor. The base film 701 may have either a single-layer or multilayer structure. In the present embodiment, a silicon nitride oxide film is formed in 10 to 400 nm thick by a plasma CVD (Chemical Vapor Deposition) method.

In the case of using a substrate containing even a small amount of alkali metal or alkali-earth metal, such as a glass substrate or a plastic substrate, as the substrate 700, it is effective to provide the base film in terms of preventing the diffusion of the impurity. However, when the diffusion of the impurity does not lead to any significant problems, for example when the quartz substrate is used, the base film 701 is not necessarily provided.

Next, an amorphous semiconductor film 702 is formed over the base film 701 in thickness from 25 to 100 nm (preferably from 30 to 60 nm) by a known method (a sputtering method, an LPCVD method, a plasma CVD method, or the like). Silicon, silicon germanium, or the like can be used as the amorphous semiconductor film 702. Silicon is used in this embodiment. In the case of using silicon germanium, the concentration of germanium is preferably in the range of approximately 0.01 to 4.5 atomic %.

Subsequently, the amorphous semiconductor film 702 is crystallized by irradiation with a laser beam 703 using a laser annealing apparatus according to the present invention as shown in FIG. 7B. In this embodiment, the laser beam 703 is emitted from a CW ceramic YAG laser. By doping the ceramic YAG with plural dopants such as Nd and Yb, multiple wavelength oscillation is achieved. The central wavelength of the fundamental wave of this laser ranges from 1030 to 1064 nm and the full width at half maximum of the oscillation wavelength is approximately 30 nm. This fundamental wavelength is converted into a second harmonic by a non-linear optical crystal inside the laser oscillator. This second harmonic has a central wavelength ranging from 515 to 532 nm and a full width at half maximum of approximately 15 nm. The laser beam is then delivered through a cylindrical lens 704.

In addition to the above-mentioned laser oscillators, a laser oscillator including a crystal of sapphire, YAG, ceramic YAG, ceramic Y₂O₃, KGW, KYW, Mg₂SiO₄, YLF, YVO₄, or GdVO₄ each of which is doped with one or more selected from Nd, Yb, Cr, Ti, Ho, and Er can be used. It is preferable to use a laser crystal doped with a plurality of dopants in order to widen the oscillation wavelength range. Some lasers can oscillate multiple wavelengths with one kind of dopant like a Tksapphire laser. The laser 703 is converted into a harmonic by a known non-linear optical element. Although the laser beam 703 is converted into the second harmonic by the non-linear optical element in this embodiment, harmonics other than the second harmonic are also applicable.

By using the above method, a crystal grain grown continuously in the scanning direction can be formed, and moreover, the formation of a microcrystal region and the unevenness can be suppressed at a boundary between the adjacent laser irradiation regions. In order to form a crystalline semiconductor film with high throughput, it is preferable to conduct the irradiation so that the adjacent laser irradiation regions overlap with each other only in their microcystal regions.

In this way, by homogeneously annealing the semiconductor film, the characteristic of electronic appliances manufactured with this semiconductor film can be made favorable and homogeneous.

After that, a crystalline semiconductor film 705 formed by the laser irradiation is shaped desirably, thereby forming an island-like semiconductor film 706 as shown in FIG. 7C. Moreover, a gate insulating film 707 is formed so as to cover the island-like semiconductor film 706.

The gate insulating film 707 may be formed with an insulating film containing at least oxygen or nitrogen and may have a single-layer or multilayer structure. As a film-forming method, a plasma CVD method or a sputtering method can be used. In this embodiment, silicon nitride oxide (SiNₓO_{y} (x>y, and x, y=1, 2, 3—)) and silicon oxynitride (SiOₓN_{y} (x>y, and x, y=1, 2, 3—)) are continuously formed 115 nm in total thickness by a plasma CVD method. In the case of forming a TFT having a channel length of 1 μm or less (also referred to as a submicron TFT), the gate insulating film 707 is desirably formed in thickness from 10 to 50 nm.

Next, a conductive film is formed over the gate insulating film 707 and shaped desirably to form a gate electrode 708, which is described as follows. First, a conductive film is formed with an electrically conductive material over the gate insulating film 707, and a multilayer of W (tungsten) and TaN (tantalum nitride) is used in this embodiment. However, a conductive film formed by stacking Mo (molybdenum), Al (aluminum), and Mo in order or a conductive film formed by stacking Ti (titanium), Al (aluminum), and Ti in order may also be used. Moreover, an element selected from gold (Au), silver (Ag), copper (Cu), platinum (Pt), aluminum (Al), molybdenum (Mo), tungsten (W), and titanium (Ti), or an alloy material or a compound material containing such an element as its main component can be used. Furthermore, a multilayer film of these materials can be used.

Then, a resist mask to pattern this conductive film is formed. First, photoresist is applied onto the conductive film by a spin coating method or the like and exposed to light. Next, heat treatment (prebake) is conducted to the photoresist. The temperature of the prebake is set in the range of 50 to 120° C., which is lower than the temperature of postbake to be conducted later. In this embodiment, the heat temperature is set to 90° C. and the heat time is set to 90 seconds.

Next, the resist which has been exposed to light is developed by dropping a developing solution onto the photoresist or spraying the developing solution from a spray nozzle.

The postbake is then conducted to the developed photoresist at 125° C. for 180 seconds so that moisture or the like remaining in the resist mask is removed and the stability against the heat is increased at the same time. By these steps, a resist mask is formed. With this resist mask, the conductive film is shaped desirably to form the gate electrode 708.

As another method, a droplet discharging method typified by a printing method or an ink jet method capable of discharging a material at a predetermined position can be used to form the gate electrode 708 directly on the gate insulating film 707.

The material to be discharged may be a solution in which a conductive material is dissolved or diffused in a solvent. As the material of the conductive film, at least one element selected from gold (Au), silver (Ag), copper (Cu), platinum (Pt), aluminum (Al), chromium (Cr), palladium (Pd), indium (In), molybdenum (Mo), nickel (Ni), lead (Pd), iridium (Ir), rhodium (Rh), tungsten (W), cadmium (Cd), zinc (Zn), iron (Fe), titanium (Ti), zirconium (Zr), and barium (Ba), or an alloy containing any one of these elements can be used. The solvent may be an organic solvent, for example, esters such as butyl acetate or ethyl acetate, alcohols such as isopropyl alcohol or ethyl alcohol, or ketones such as methyl ethyl ketone or acetone.

The viscosity of the composition is 300 cp or less in order to prevent drying and to facilitate the discharging of the composition from a discharge outlet. The viscosity and the surface tension of the composition may be appropriately adjusted in accordance with the solvent and the intended purpose.

After that, an impurity element imparting n-type or p-type conductivity is selectively added to the island-like semiconductor film 706 by using the gate electrode 708 or the resist used when forming the gate electrode 708 as a mask so that a source region 709, a drain region 710, an LDD region 711, and the like are formed. By the above process, N-channel TFTs 712 and 713 and a P-channel TFT 714 can be formed over the same substrate (FIG. 7D).

Subsequently, as shown in FIG. 7D, an insulating film 715 is formed as a protective film to protect those TFTs. This insulating film 715 is formed in a single-layer or multilayer structure of a silicon nitride film or a silicon nitride oxide film in thickness from 100 to 200 nm by a plasma CVD method or a sputtering method. In the case of combining a silicon nitride oxide film and a silicon oxynitride film, these films can be formed continuously by switching gas. In this embodiment, a silicon oxynitride film is formed in 100 nm thick by a plasma CVD method. By the provision of the insulating film 715, a blocking effect to block the intrusion of various ionic impurities and oxygen and moisture in the air can be obtained.

Next, an insulating film 716 is further formed. In this embodiment, an organic resin film such as polyimide, polyamide, BCB (benzocyclobutene), acrylic, or siloxane, an inorganic interlayer insulating film (an insulating film containing silicon such as silicon nitride or silicon oxide), a low-k (low dielectric constant) material, or the like can be used. Siloxane is a material whose skeletal structure includes a bond of silicon and oxygen and which has a structure in which silicon is bonded with at least one of fluorine, aliphatic hydrocarbon, and aromatic hydrocarbon. Since the insulating film 716 is formed mainly for the purpose of relaxing and flattening the unevenness due to the TFTs formed over the glass substrate, a film being superior in flatness is preferable.

Moreover, the gate insulating film 707 and the insulating films 715 and 716 are patterned by a photolithography method to form contact holes that reach the source region 709 and the drain region 710.

Next, a conductive film is formed with a conductive material, and a wiring 717 is formed by patterning the conductive film. After that, an insulating film 718 is formed as a protective film, thereby completing a semiconductor device shown in FIG. 7D.

It is to be noted that the method for manufacturing a semiconductor device using the laser annealing method of the present invention is not limited to the above method for manufacturing a TFT. By using the semiconductor film crystallized with the use of the laser beam irradiation method of the present invention as an active layer of a TFT, the variation in the mobility, threshold, and on-current between the elements can be suppressed.

Before the laser crystallization step, a crystallization step using a catalytic element may be provided. As the catalyst element, nickel (Ni), germanium (Ge), iron (Fe), palladium (Pd), tin (Sn), lead (Pb), cobalt (Co), platinum (Pt), copper (Cu), or gold (Au) can be used.

It is to be noted that the crystallization may be performed in such a way that after the catalytic element is added, the heat treatment is performed in order to promote the crystallization, and then the laser irradiation is conducted. Alternatively, the heat treatment may be omitted. Further, after the heat treatment, the laser process may be performed while keeping the temperature.

Although the present embodiment has shown an example in which the semiconductor film is crystallized by the laser irradiation method of the present invention, the laser irradiation method may be applied to activate the impurity element added in the semiconductor film. Moreover, the method for manufacturing a semiconductor device of the present invention can be applied to a method for manufacturing an integrated circuit and a semiconductor display device.

By using the present invention, the semiconductor film can be homogeneously annealed. Therefore, all the TFTs manufactured by using the semiconductor film formed by the present invention have superior characteristics and the characteristics of the respective TFTs are homogeneous.

This embodiment can be freely combined with Embodiment Mode or another Embodiment.

### Embodiment 3

This embodiment will describe an example of conducting crystallization more favorably by combining a crystallization method by a laser irradiation apparatus of the present invention with a crystallization method by a catalytic element.

First, the process up to the steps of forming a base film 801 over a substrate 800 and forming a semiconductor film 802 over the base film 801 is performed as shown in FIG. 8A with reference to Embodiment 2. Next, as shown in FIG. 8B, a solution of a nickel compound, for example a nickel acetate solution, containing Ni in the range of 10 to 100 ppm in weight is applied to the surface of the semiconductor film 802 by a spin coating method. It is noted that a dotted line in FIG. 8B shows that the catalytic element has been added. The catalytic element may be added not only by the above method but also by another method such as a sputtering method, an evaporation method, or a plasma process.

Next, the heat treatment is performed for 4 to 24 hours at 500 to 650° C., for example for 14 hours at 570° C. This heat treatment forms a semiconductor film 803 in which the crystallization is promoted in a vertical direction from the surface where the nickel acetate solution has been added toward the substrate 800 (FIG. 8C).

The heat treatment may be performed at a set heat temperature of 740° C. for 180 seconds by RTA (Rapid Thermal Anneal) using radiation of a lamp as a heat source or by RTA using heated gas (gas RTA). The set temperature is the temperature of the substrate measured by a pyrometer, and the measured temperature is herein defined as the set temperature in the heat treatment. As another method, heat treatment using an annealing furnace at 550° C. for 4 hours may also be employed. It is the action of the metal element having the catalytic activity that lowers the temperature and shortens the time of the crystallization.

Although the present embodiment uses nickel (Ni) as the catalytic element, another element such as germanium (Ge), iron (Fe), palladium (Pd), tin (Sn), lead (Pb), cobalt (Co), platinum (Pt), copper (Cu), or gold (Au) may also be used.

Subsequently, the semiconductor film 803 is crystallized with the laser irradiation apparatus shown in Embodiment 1. A laser crystal of the laser oscillator used in this embodiment is ceramic YAG. By doping the ceramic YAG with plural dopants such as Nd and Yb, multiple wavelength oscillation is obtained. The central wavelength of the fundamental wave of a laser 804 ranges from 1030 to 1064 nm and the full width at half maximum of the oscillation wavelength is approximately 30 nm. This wavelength is converted into a second harmonic by a non-linear optical crystal inside the laser oscillator. This second harmonic has a central wavelength ranging from 515 to 532 nm and a full width at half maximum of approximately 15 nm.

By irradiating the semiconductor film 803 with the laser beam 804, a semiconductor film 805 in which the crystallinity has been enhanced is formed. It is considered that the semiconductor film 805 crystallized using the catalytic element contains the catalytic element (herein Ni) at a concentration of approximately 1×10¹⁹ atoms/cm³. Therefore, the gettering of the catalytic element existing in the semiconductor film 805 is performed next. Since the metal element in the semiconductor film 805 can be removed by the gettering, the off-current can be reduced.

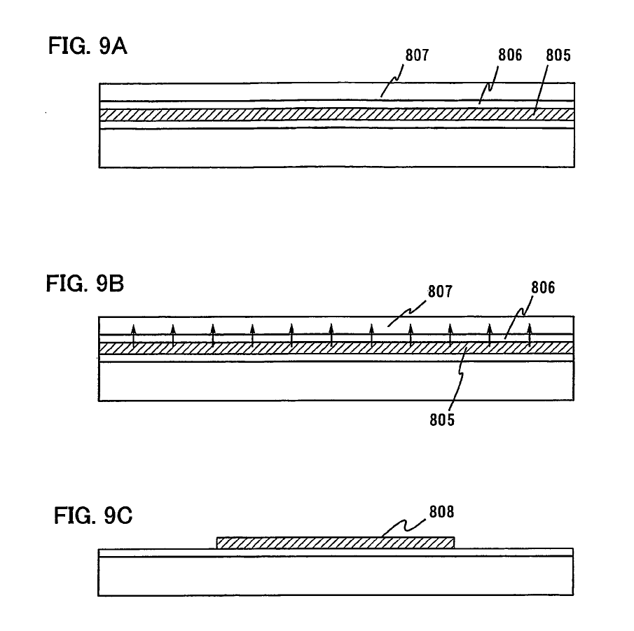

First, an oxide film 806 is formed over a surface of the semiconductor film 805 as shown in FIG. 9A. By forming the oxide film 806 in approximately 1 to 10 nm thick, it is possible to prevent the surface of the semiconductor film 805 from becoming rough in a later etching step. The oxide film 806 can be formed by a known method. For example, the oxide film 806 may be formed by oxidizing the surface of the semiconductor film 805 using ozone water or using a solution in which a hydrogen peroxide solution is mixed with sulfuric acid, hydrochloric acid, nitric acid, or the like. Alternatively, the oxide film 806 may be formed by a plasma process, heat treatment, ultraviolet ray irradiation, or the like in an atmosphere containing oxygen. Moreover, the oxide film 806 may be formed separately by a plasma CVD method, a sputtering method, an evaporation method, or the like.

A semiconductor film 807 for the gettering which contains a noble gas element at a concentration of 1×10²⁰ atoms/cm³ or more is formed in 25 to 250 nm thick over the oxide film 806 by a sputtering method. It is desirable that the mass density of the semiconductor film 807 for the gettering be lower than that of the semiconductor film 805 in order to increase the selecting ratio at the etching between the semiconductor film 807 and the semiconductor film 805. As the noble gas element, one or more of elements selected from helium (He), neon (Ne), argon (Ar), krypton (Kr), and xenon (Xe) are used.

Next, the gettering is performed by heat treatment according to a furnace annealing method or an RTA method as shown in FIG. 9B. When the furnace annealing method is employed, heat treatment is performed for 0.5 hours to 12 hours at 450 to 600° C. in a nitrogen atmosphere. When the RTA method is employed, a lamp light source for heating is turned on for 1 to 60 seconds, preferably 30 to 60 seconds, which is repeated from 1 to 10 times, preferably from 2 to 6 times. The luminance intensity of the lamp light source is set so that the semiconductor film is heated instantaneously at 600 to 1000° C., preferably at approximately 700 to 750° C.

Through the heat treatment, the catalytic element inside the semiconductor film 805 is moved to the semiconductor film 807 for the gettering due to the diffusion as indicated by an arrow, and the catalytic element is thus gettered.

Next, the semiconductor film 807 for the gettering is removed by etching selectively. The etching process is performed by dry etching using ClF₃ not applying plasma or by wet etching using an alkali solution such as a solution containing hydrazine or tetraethylammonium hydroxide ((CH₃)₄NOH). At this time, the oxide film 806 can prevent the semiconductor film 805 from being etched.

Next, after removing the oxide film 806 by hydrofluoric acid, the semiconductor film 805 is shaped desirably to form an island-like semiconductor film 808 (FIG. 9C). Various semiconductor elements, typically TFTs, can be formed using the island-like semiconductor film 808. It is noted that the gettering step in the present invention is not limited to the method shown in this embodiment. Another method may also be employed to decrease the catalytic element in the semiconductor film.

The laser irradiation melts an upper part of the semiconductor film but does not melt a lower part of the semiconductor film. Therefore, a crystal remaining without being melted in the lower part of the semiconductor film becomes a crystal nucleus, and the crystallization is promoted from the lower part toward the upper part of the semiconductor film. Moreover, the crystal orientation is easily aligned. Therefore, the surface is prevented from becoming rough compared with the case of Embodiment Mode. Further, the variation in the characteristics of the semiconductor elements to be formed afterward, typically TFTs, can be suppressed further.

It is noted that this embodiment has described the structure to promote crystallization by performing the heat treatment after the catalytic element is added and to enhance crystallinity further by the laser irradiation. However, the present invention is not limited to this, and the heat treatment may be omitted. Specifically, after adding the catalyst element, the laser irradiation may be conducted instead of the heat treatment in order to enhance the crystallinity.

This embodiment can be freely combined with Embodiment Mode or another Embodiment.

### Embodiment 4

This embodiment will describe a light-emitting device using a light-emitting element formed by using a TFT manufactured in another Embodiment. In this embodiment, a structural diagram of a light-emitting device in which light is extracted from a rear surface of a substrate with its top surface having an insulating surface thereover. A light-emitting device which can be manufactured by using the present invention is not limited to this structure. The present invention can be applied to either a light-emitting device in which light can be extracted from a top surface of the substrate having an insulating surface or a light-emitting device in which light can be extracted from both of the top and rear surfaces of the substrate.

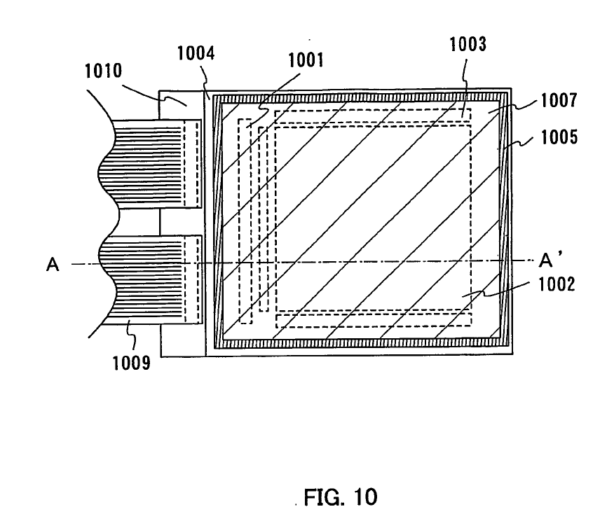

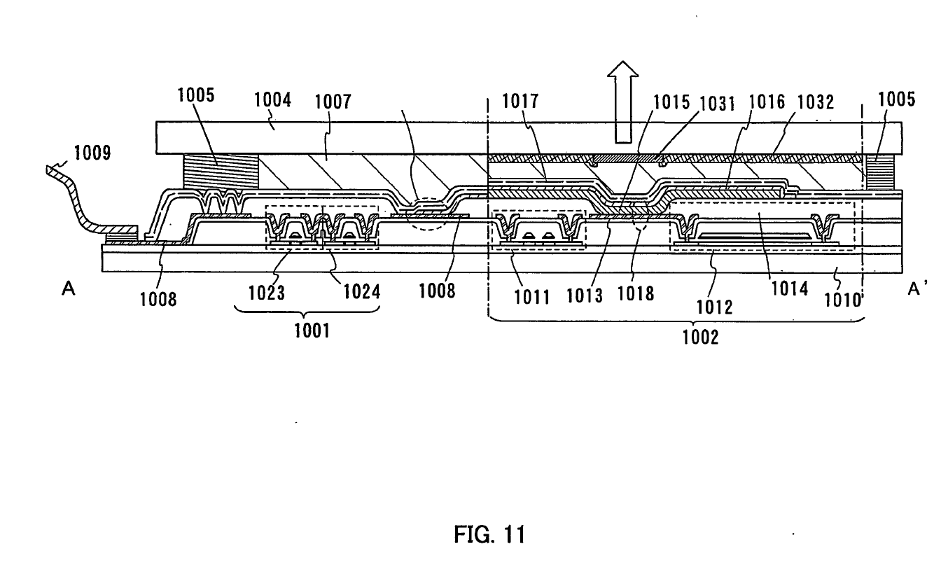

FIG. 10 is a top view of the light-emitting device and FIG. 11 is a cross-sectional view taken along A-A′ of FIG. 10. A reference numeral 1001 denotes a source signal line driver circuit; 1002, a pixel portion; and 1003, a gate side driver circuit all of which are illustrated with a dotted line. Moreover, a reference numeral 1004 denotes a transparent sealing substrate; 1005, a first sealing material; and 1007, a second sealing material which is transparent and which fills an inside surrounded by the first sealing material 1005. The first sealing material 1005 contains a gap material for holding an interval between the substrates.

A reference numeral 1008 denotes a connection wiring for transmitting a signal which will be inputted into the source side driver circuit 1001 and the gate side driver circuit 1003 and receiving a video signal or a clock signal from an FPC (flexible printed circuit) 1009 to be an external input terminal. Although the FPC 1009 is illustrated alone here, this FPC may have a print wiring board (PWB) attached thereto.

Next, the cross-sectional structure is described with reference to FIG. 11. Although a driver circuit and a pixel portion are formed over the substrate 1010, the source side driver circuit 1001 and the pixel portion 1002 are shown as the driver circuit.

In the source side driver circuit 1001, a CMOS circuit in which an n-channel TFT 1023 and a p-channel TFT 1024 are combined is formed. Moreover, TFTs for forming the driver circuit may be formed with a known CMOS circuit, PMOS circuit, or NMOS circuit. Although this embodiment shows a driver-integrated type in which the driver circuit is formed over the substrate, the present invention is not limited to this and the driver circuit may be formed outside the substrate, not over the substrate. Moreover, the structure of the TFT which uses a poly-silicon film as an active layer is not limited in particular, and both of a top-gate TFT and a bottom-gate TFT are applicable.

Moreover, the pixel portion 1002 is formed by a plurality of pixels each including a switching TFT 1011, a current control TFT 1012, and a first electrode (anode) 1013 electrically connected to a drain of the current control TFT 1012. The current control TFT 1012 may be either an n-channel TFT or a p-channel TFT; however, the current control TFT 1012 is preferably a p-channel TFT in the case of connecting to the anode. Moreover, a capacitor (not shown) is preferably provided as appropriate. Here, in this example, only the cross-sectional structure of one pixel among an infinite number of pixels arranged is shown and two TFTs are used in the one pixel; however, three or more TFTs may be appropriately used.

Since the first electrode (anode) 1013 is in direct contact with a drain of the TFT here, it is desirable that a lower layer of the first electrode (anode) 1013 be formed with a material having an ohmic contact with the drain including silicon and an uppermost layer to be in contact with a layer containing an organic compound be formed with a material having a high work function. The first electrode (anode) desirably has a work function of 4.0 eV or more. For example, when the first electrode is formed in a three-layer structure of a titanium nitride film, a film containing aluminum as its main component, and a titanium nitride film, the resistance as the wiring can be made low, favorable ohmic contact can be obtained, and the first electrode can function as an anode. Moreover, the first electrode (anode) 1013 may be formed in a single-layer structure of ITO (indium tin oxide), ITSO (indium oxide to which silicon oxide (SiO₂) is mixed for 2 to 20 wt %), gold (Au), platinum (Pt), nickel (Ni), tungsten (W), chromium (Cr), molybdenum (Mo), iron (Fe), cobalt (Co), copper (Cu), palladium (Pd), or zinc (Zn), or metal nitride (such as titanium nitride). Alternatively, the first electrode may be formed by stacking three or more layers.

Moreover, an insulator 1014 (also referred to as a bank, a partition wall, a barrier wall, an embankment, or the like) is formed at opposite ends of the first electrode (anode) 1013. The insulator 1014 may be formed with an organic resin film or an insulating film containing silicon. Here, an insulator having a shape shown in FIG. 11 is formed as the insulator 1014 by using a positive photosensitive acrylic resin film.

In order to form a film favorably in a later step, the insulator 1014 is made to have curvature at its upper end portion or lower end portion. For example, in the case of using a positive photosensitive acrylic as a material of the insulator 1014, it is preferable that only the upper end portion of the insulator 1014 have a radius of curvature (0.2 to 3 μm). Moreover, as the insulator 1014, either a negative type which becomes insoluble in etchant by light exposure or a positive type which becomes soluble in etchant by light exposure can be used.

The insulator 1014 may be covered with an aluminum nitride film, an aluminum nitride oxide film, a thin film containing carbon as its main component, or a protective film including a silicon nitride film.

Next, an electroluminescent layer 1015 is formed. As a material for forming the electroluminescent layer 1015, a low-molecular-weight material, a high-molecular-weight material, and a medium-molecular-weight material having an intermediate property between the high-molecular-weight material and the low-molecular-weight material are given. In this embodiment, since the electroluminescent layer 1015 is formed by an evaporation method, the low-molecular-weight material is used. Both of the low-molecular-weight material and the high-molecular weight material can be applied by spin coating or an ink jet method when the material is dissolved in a solvent. Further, not only an organic material but also a compound material including an organic material and an inorganic material can be used.

Moreover, the electroluminescent layer 1015 is selectively formed over the first electrode (anode) 1013. For example, the evaporation is conducted in a film-forming chamber which is evacuated until the degree of vacuum decreases to 5×10⁻³ Torr (0.665 Pa) or less, preferably 10⁻⁴ to 10⁻⁶ Torr (which means, 1.333×10⁻⁴ to 1.333×10⁻² Pa). At the evaporation, the organic compound is vaporized in advance by being heated, and the vaporized organic compound is deposited to form the electroluminescent layer 1015 (a hole-injecting layer, a hole-transporting layer, a light-emitting layer, an electron-transporting layer, and an electron-injecting layer from the first electrode side). The electroluminescent layer 1015 may have, instead of such a multilayer structure, a single-layer structure or a mixed-layer structure. Moreover, a second electrode (cathode) 1016 is formed over the electroluminescent layer 1015.

As the second electrode 1016 (cathode), it is preferable to use metal, alloy, an electrically conductive compound, a mixture of these, or the like each having the work function as low as approximately 3.8 eV or less. Specifically, the cathode can be formed with a material such as an element belonging to the first group or the second group in the periodic table, for example alkali metal such as Li or Cs; Mg; alkali-earth metal such as Ca or Sr; alloy including these such as Mg:Ag or Al:Li; a chemical compound such as LiF, CsF, or CaF₂; or transition metal including a rare-earth metal (such as Yb). However, in order that the second electrode 1016 (cathode) has a light-transmitting property in this embodiment, the second electrode is formed by forming these metals or the alloy including these metals extremely thinly and by stacking ITO, IZO (indium zinc oxide: indium oxide to which zinc oxide is added for 2 to 20 atomic %), ITSO, or another metal (including alloy).

Here, the second electrode (cathode) 1016 is formed with a multilayer of a thin metal film having a low work function and a transparent conductive film (such as ITO, IZO, or ZnO) so that the emitted light passes therethrough. In this way, an electroluminescent element 1018 including the first electrode (anode) 1013, the electroluminescent layer 1015, and the second electrode (cathode) 1016 is formed.

In this embodiment, the electroluminescent layer 1015 is formed by sequentially stacking Cu—Pc (20 nm) as a hole-injecting layer, α-NPD (30 nm) as a first light-emitting layer having a hole-transporting property, a material (20 nm) in which Pt (ppy) acac: 15 wt % is added into CBP as a second light-emitting layer, and BCP (30 nm) as an electron-transporting layer. Since a metal thin film having a low work function is used as the second electrode (cathode) 1016, an electron-injecting layer (CaF₂) is not necessary here.

The electroluminescent element 1018 formed thus emits white light. In order to achieve full color, a color filter including a colored layer 1031 and a light-blocking layer (BM) 1032 (an overcoat layer is not shown here for simplicity) is provided.

Moreover, a transparent protective layer 1017 is formed to seal the electroluminescent element 1018. This transparent protective layer 1017 includes a multilayer of a first inorganic insulating film, a stress relaxing film, and a second inorganic insulating film. The first inorganic insulating film and the second inorganic insulating film can be formed with a silicon nitride film, a silicon oxide film, a silicon nitride oxide film (SiNO film (composition ratio N>O)), a silicon oxynitride film (SiON film (composition ratio N<O)), or a thin film containing carbon as its main component (for example, a DLC film or a CN film) formed by a sputtering method or a CVD method. These inorganic insulating films have a high blocking effect against moisture; however, the inorganic insulating films are easier to be peeled as the film becomes thicker because the film stress increases.

However, when the stress relaxing film is interposed between the first inorganic insulating film and the second inorganic insulating film, moisture can be absorbed as well as the stress can be relaxed. Even through a microscopic hole (such as a pinhole) is formed in the first inorganic insulating film from any cause at the film formation, the stress relaxing film can cover the hole, and extremely high blocking effect can be obtained against moisture or oxygen by providing the second inorganic insulating film thereover.

The stress relaxing film is preferably formed with a moisture-absorbing material which has smaller stress than the inorganic insulating films. Moreover, the stress relaxing film desirably has a light-transmitting property. Further, a film containing an organic compound such as α-NPD, BCP (bathocuproin), MTDATA, AIq₃, or the like may be used as the stress relaxing film. These films have a moisture-absorbing property and are almost transparent if the films are thin. Moreover, since MgO, Sro₂, and SrO have a moisture-absorbing property and a light-transmitting property, these materials can be used for the stress relaxing film.

In this embodiment, at least one of the first inorganic insulating film and the second inorganic insulating film is formed with a film formed by using a silicon target in an atmosphere including nitrogen and argon, that is, a silicon nitride film having a high blocking effect against impurities such as moisture and alkali metal, and the stress relaxing film is formed with a thin film of AIq₃ by an evaporation method. The total film thickness of the transparent protective layer is preferably made as small as possible to make the emitted light pass through the transparent protective layer.

Further, a sealing substrate 1004 is pasted to seal the electroluminescent element 1018 in an inert gas atmosphere by the first sealing material 1005 and the second sealing material 1007. It is preferable to use an epoxy resin as the first sealing material 1005 and the second sealing material 1007. Further, the first sealing material 1005 and the second sealing material 1007 are desirably materials which do not transmit moisture or oxygen as much as possible.

In this embodiment, the sealing substrate 1004 may be a glass substrate, a quartz substrate, or a plastic substrate made of FRP (Fiberglass-Reinforced Plastics), PVF (polyvinyl fluoride), polyester, acrylic, or the like. Moreover, it is possible to seal with a third sealing material so as to cover a side surface (exposed surface) after pasting the sealing substrate 1004 with the first sealing material 1005 and the second sealing material 1007.

In this way, the electroluminescent element 1018 is sealed with the first sealing material 1005 and the second sealing material 1007, thereby completely shielding the electroluminescent element 1018 from outside and preventing the intrusion of materials promoting deterioration of the electroluminescent layer 1015 such as moisture or oxygen from outside. Therefore, a light-emitting device with high reliability can be obtained.

Further, a dual-emission type light-emitting device can be manufactured by using a transparent conductive film as the first electrode (anode) 1013.

This embodiment can be freely combined with Embodiment Mode or another Embodiment. Moreover, not only the display device using the light-emitting element but also a display device using a liquid crystal can be manufactured by using a semiconductor film crystallized by the present invention.

### Embodiment 5

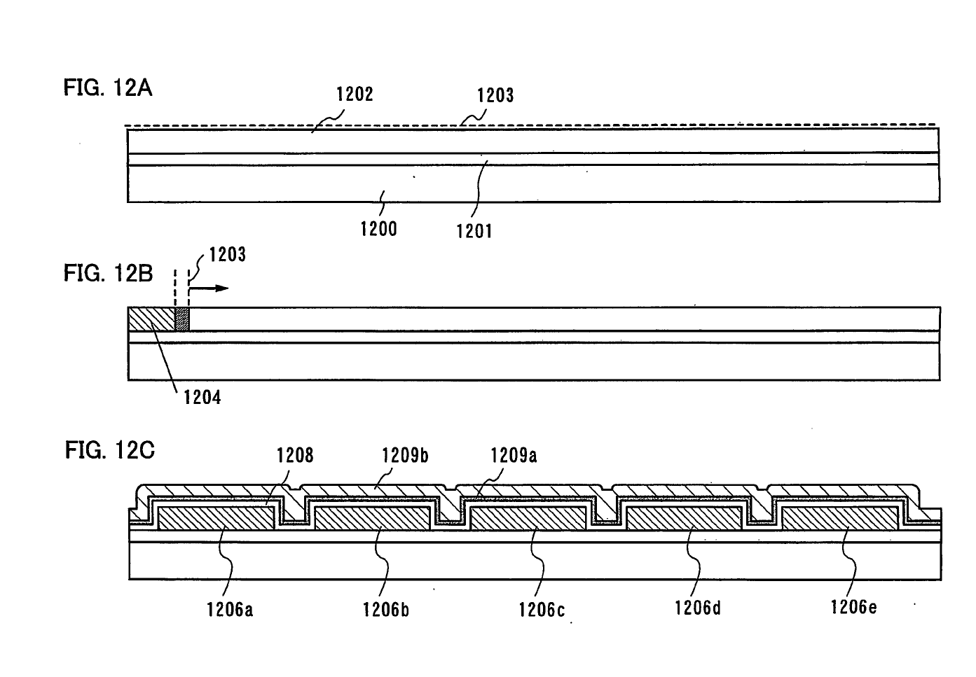

This embodiment describes an example of manufacturing a CPU (Central Processing Unit) as one semiconductor device which is manufactured using the present invention with reference to FIGS. 12A to 16.

As shown in FIG. 12A, a base insulating film 1201 is formed over a substrate 1200 having an insulating surface. The substrate 1200 may be, for example, a glass substrate made of barium borosilicate glass, alumino borosilicate glass, or the like. In addition, although a substrate made of flexible synthetic resin such as acrylic or plastic typified by PET, PES, or PEN, or the like tends to be inferior to other substrates in point of the heat resistance, the substrate made of flexible synthetic resin can be used when the substrate can resist the process temperature in the manufacturing process.

The base insulating film 1201 is provided in order to prevent alkali-earth metal or alkali metal such as Na included in the substrate 1200 from diffusing into a semiconductor film. Alkali-earth metal or alkali metal causes an adverse effect on the characteristic of the semiconductor element when alkali-earth metal or alkali metal is in the semiconductor. Therefore, the base insulating film is formed with an insulating material such as silicon oxide, silicon nitride, or silicon oxide containing nitrogen, which can suppress the diffusion of alkali-earth metal and alkali metal into the semiconductor film.

Next, an amorphous semiconductor film 1202 is formed over the base insulating film 1201 in thickness from 25 to 100 nm (preferably from 30 to 60 nm). The amorphous semiconductor film 1202 may be formed with silicon or silicon germanium. When silicon germanium is used, it is preferable that the concentration of germanium be in the range of approximately 0.01 to 4.5 atomic %. Here, a semiconductor film containing silicon as its main component (also referred to as an amorphous silicon film or amorphous silicon) is formed in 66 nm thick.

After that, the amorphous semiconductor film 1202 is irradiated with a laser 1203 as described in Embodiment Mode or another Embodiment (FIG. 12B). By this laser irradiation, the amorphous semiconductor film 1202 is crystallized to form a semiconductor film 1204 having a crystal structure (here a poly-silicon film).

Next, as shown in FIG. 12C, the semiconductor film having the crystal structure is shaped into a predetermined form to obtain island-like semiconductor layers 1206a to 1206e.

Next, if necessary, a small amount of impurity elements (such as boron) is added to make the threshold as an electric characteristic of a thin film transistor closer to zero.

Next, an insulating film to cover the island-like semiconductor layers 1206a to 1206e, which is a so-called gate insulating film 1208, is formed. Before forming the gate insulating film 1208, the surfaces of the island-like semiconductor layers are washed with fluorine acid or the like. The gate insulating film 1208 is formed with an insulating film containing silicon in thickness from 10 to 150 nm, preferably from 20 to 40 nm, by a plasma CVD method or a sputtering method. The gate insulating film 1208 is not limited to a silicon oxide film and another insulating film containing silicon (such as a silicon nitride film or a silicon oxynitride film) may be formed in a single-layer or multilayer structure. Further, in the case of employing a multilayer of a silicon nitride oxide film and a silicon oxynitride film as the gate insulating film 1208, the films may be formed continuously by switching gas.

After that, a first conductive film 1209a and a second conductive film 1209b to be a gate electrode are formed over the gate insulating film 1208. Although the gate electrode has a two-layer structure here, the gate electrode may have a single-layer structure or a multilayer structure of three or more layers. The first and second conductive films 1209a and 1209b may be formed with an element selected from Ta, W, Ti, Mo, Al, and Cu or an alloy material or a compound material containing any one of these elements as its main component.

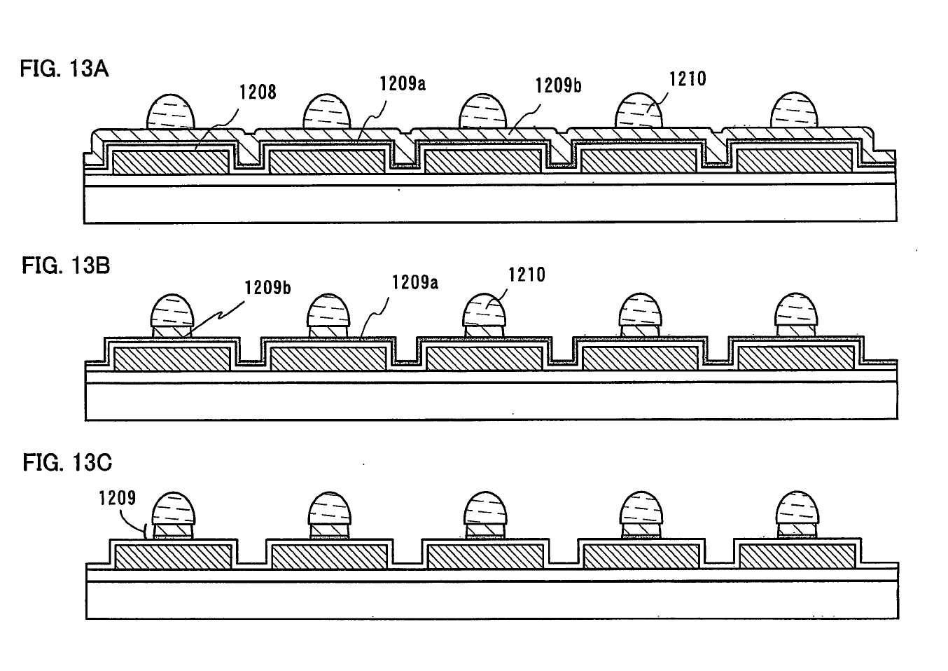

Next, as shown in FIG. 13A, a resist mask 1210 is formed to etch the first conductive film 1209a and the second conductive film 1209b. The resist mask 1210 only needs to have a tapered end portion and may have a sector shape or a trapezoid shape.

Subsequently, the second conductive film 1209b is selectively etched by using the resist mask 1210 as shown in FIG. 13B. The first conductive film 1209a serves as an etching stopper so that the gate insulating film 1208 and the semiconductor films 1206a to 1206e are not etched. The etched second conductive film 1209b has a gate length from 0.2 to 1.0 μm.

Next, the first conductive film 1209a is etched with the resist mask 1210 provided as shown in FIG. 13C. At this time, the first conductive film 1209a is etched under a condition where a selective ratio between the gate insulating film 1208 and the first conductive film 1209a is high. In this step, the resist mask 1210 and the second conductive film 1209b may be etched to some extent and be narrower. Thus, a very small gate electrode 1209 having a gate length of 1.0 μm or less is formed.

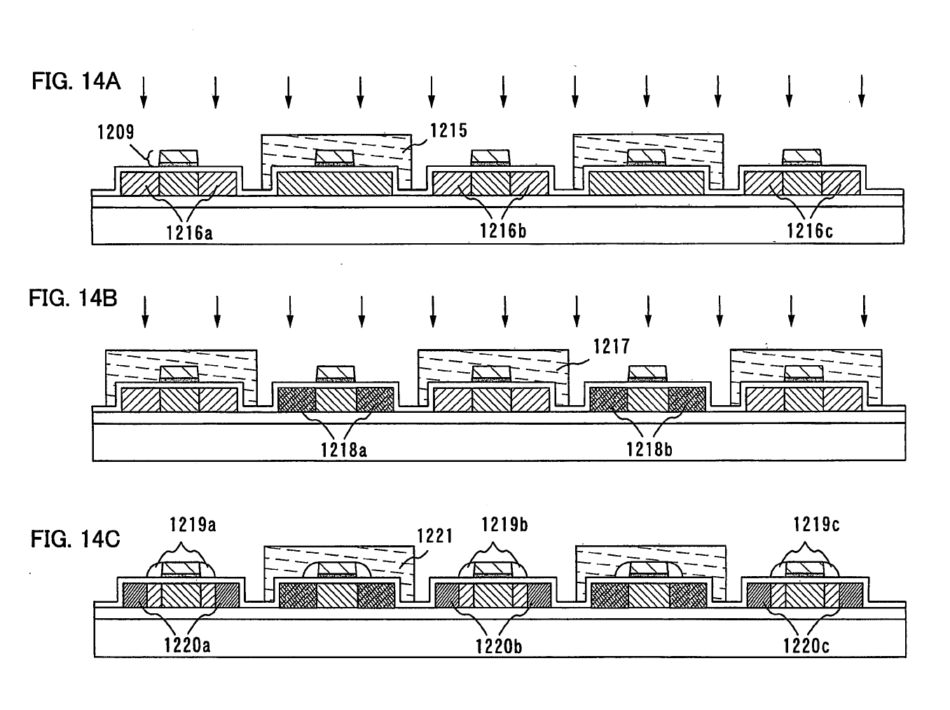

Next, as shown in FIG. 14A, the resist mask 1210 is removed by O₂ ashing or a resist peeling solution and then a resist mask 1215 for adding impurities is appropriately formed. Here, the resist mask 1215 is formed so as to cover regions to become p-channel TFTs.

Next, phosphorus (P), which is an impurity element, is added in a self-aligning manner in a region to be an n-channel TFT by using the gate electrode 1209 as a mask. Here, phosphine (PH₃) is added at 60 to 80 keV. With this step, impurity regions 1216a to 1216c are formed in the regions to be n-channel TFTs.

Subsequently, the resist mask 1215 is removed, and a resist mask 1217 is formed so as to cover the regions to be n-channel TFTs. Then, boron (B), which is an impurity element, is added in a self-aligning manner by using the gate electrode 1209 as a mask as shown in FIG. 12B. With this step, impurity regions 1218a and 1218b are formed in the regions to become p-channel TFTs.

Next, after removing the resist mask 1217, an insulating film covering side surfaces of the gate electrode 1209, which is so-called sidewalls 1219a to 1219c, are formed. The sidewalls 1219a to 1219c can be formed by etching an insulating film containing silicon formed by a plasma CVD method or a low-pressure CVD (LPCVD) method.

Subsequently, a resist mask 1221 is formed over the p-channel TFT, and then phosphine (PH₃) is added at 15 to 25 keV to form high-concentration impurity regions, which are so-called source region and drain region. With this step, high-concentration impurity regions 1220a to 1220c are formed in a self-aligning manner by using the sidewalls 1219a to 1219c as a mask as shown in FIG. 14C.

Next, the resist mask 1221 is removed by O₂ ashing or a resist peeling solution.

Then, heat treatment is conducted to activate each impurity region. Here, the impurity regions are activated using the laser irradiation method shown in Embodiment Mode or another Embodiment. Further, the impurity regions may be activated by heating the substrate at 55O° C. in a nitrogen atmosphere.

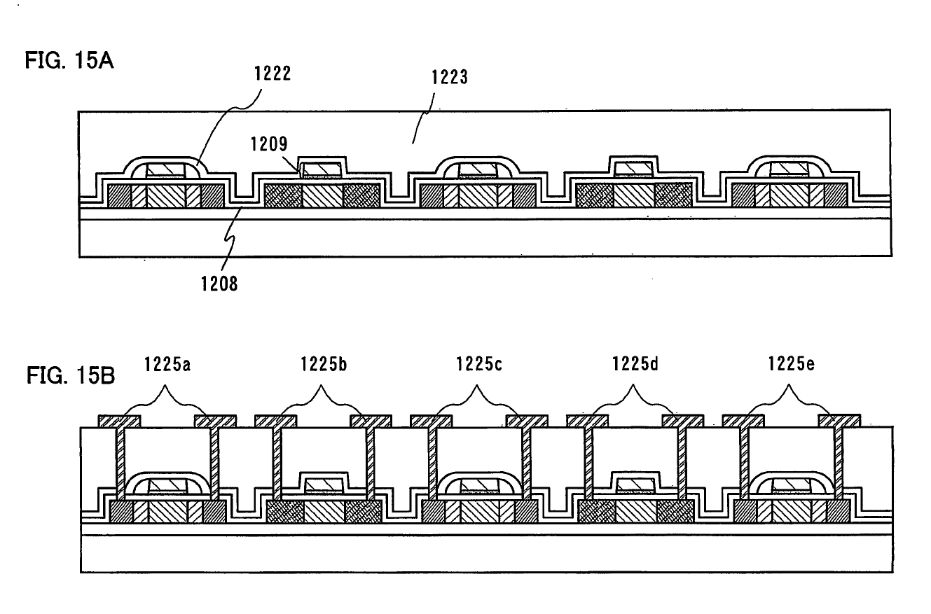

Next, a first interlayer insulating film 1222 for covering the gate insulating film 1208 and the gate electrode 1209 is formed as shown in FIG. 15A. The first interlayer insulating film 1222 is formed with an inorganic insulating film containing hydrogen such as a silicon nitride film.

After that, heat treatment is conducted for hydrogenation. With the hydrogen emitted from the silicon nitride film serving as the first interlayer insulating film 1222, a dangling bond in the silicon oxide film and the silicon film is terminated.

Next, a second interlayer insulating film 1223 is formed so as to cover the first interlayer insulating film 1222 as shown in FIG. 15A. The second interlayer insulating film 1223 is formed with an inorganic material (such as silicon oxide, silicon nitride, or silicon nitride containing oxygen), a photosensitive or non-photosensitive organic material (such as polyimide, acrylic, polyamide, polyimide-amide, resist, or benzocyclobutene), siloxane, or a multilayer structure of these materials. Siloxane is a material whose skeletal structure includes a bond of silicon and oxygen and which has a structure in which silicon is bonded with at least one of fluorine, aliphatic hydrocarbon, and aromatic hydrocarbon.

Subsequently, an opening portion, which is a so-called contact hole, is formed in the gate insulating film 1208, the first insulating film 1222, and the second insulating film 1223. Then, wirings 1225a to 1225e to be connected to the respective impurity regions are formed as shown in FIG. 15B. If necessary, a wiring to be connected to the gate electrode is also formed simultaneously. These wirings may be formed with a film or an alloy film which contains aluminum (Al), titanium (Ti), molybdenum (Mo), tungsten (W), or silicon (Si). In addition, these wirings may be formed with at least one element selected from nickel, cobalt, and iron, or an aluminum alloy film containing carbon.

In this way, an n-channel thin film transistor having an LDD structure formed to have a low-concentration impurity region and having a gate length of 1.0 μm or less can be formed. Moreover, a p-channel thin film transistor having a single drain structure formed so as not to have a low-concentration impurity region and having a gate length of 1.0 μm or less is completed. A TFT having a gate length of 1.0 μm or less can be referred to as a submicron TFT. Since a short-channel effect and deterioration due to hot carriers are difficult to occur in the p-channel thin film transistor, the single drain structure can be employed.

In the present invention, the p-channel thin film transistor may have an LDD structure. Moreover, the n-channel thin film transistor and the p-channel thin film transistor may have, instead of the LDD structure, a so-called GOLD structure in which the low-concentration impurity region overlaps the gate electrode.

Thus, a semiconductor device having the thin film transistor formed thus, which is a CPU in this embodiment, can be manufactured. The semiconductor device can operate at high speed with an operation frequency of 30 MHz at a drive voltage of 5 V.

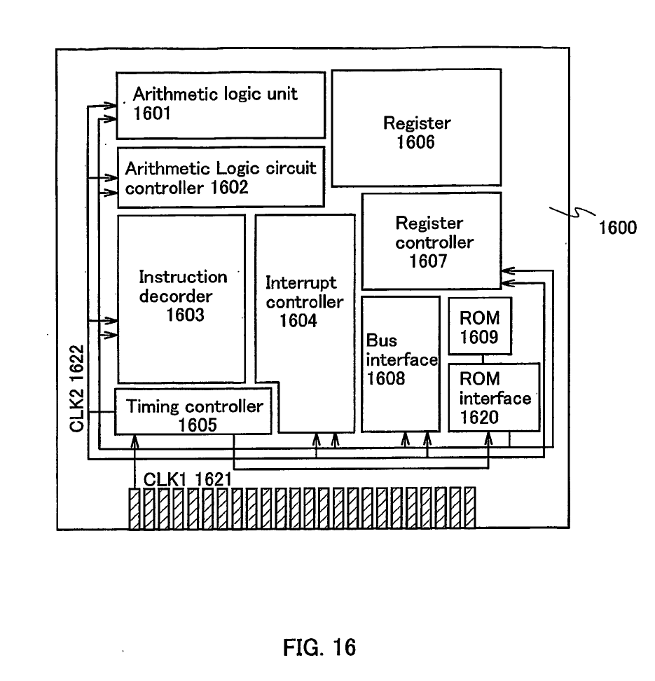

Next, an example of constituting various circuits with the above thin film transistor is described with reference to FIG. 16. FIG. 16 is a block diagram of a CPU formed over a glass substrate 1600.

A CPU shown in FIG. 16 mainly includes an arithmetic circuit (ALU: arithmetic logic unit) 1601, an arithmetic circuit controlling portion (ALU controller) 1602, an instruction decoding portion (instruction decoder) 1603, an interrupt controlling portion (interrupt controller) 1604, a timing controlling portion (timing controller) 1605, a register (register) 1606, a register controlling portion (register controller) 1607, a bus interface (bus I/F) 1608, a rewritable ROM 1609, and a ROM interface (ROM I/F) 1620 over a substrate 1600. The ROM 1609 and the ROM I/F 1620 may be provided to another chip.

The CPU shown in FIG. 16 is just an example in which the structure is simplified, and actual CPUs have various structures according to their intended purposes.

An instruction inputted into the CPU through the bus interface 1608 is inputted into the instruction decoding portion 1603 and decoded, and then inputted into the arithmetic circuit controlling portion 1602, the interrupt controlling portion 1604, the register controlling portion 1607, and the timing controlling portion 1605.

The arithmetic circuit controlling portion 1602, the interrupt controlling portion 1604, the register controlling portion 1607, and the timing controlling portion 1605 conduct various controls based on the decoded instructions. Specifically, the arithmetic circuit controlling portion 1602 generates signals for controlling the operation of the arithmetic circuit 1601. Further, the interrupt controlling portion 1604 processes an interrupt request from the peripheral circuit or an external input/output device during the execution of a program of the CPU by judging from the priority or the mask condition. The register controlling portion 1607 generates an address of the register 1606 and reads from or writes in the register 1606 in accordance with the condition of the CPU.

The timing controlling portion 1605 generates signals for controlling the timing of the operation of the arithmetic circuit 1601, the arithmetic circuit controlling portion 1602, the instruction decoding portion 1603, the interrupt controlling portion 1604, and the register controlling portion 1607. For example, the timing controlling portion 1605 is equipped with an internal clock generating portion that generates an internal clock signal CLK2 (1622) based on a standard clock signal CLK1 (1621) and supplies the clock signal CLK2 to the above various circuits.

Since a large area can be irradiated with a laser beam by scanning once according to the present invention, a high-quality CPU can be manufactured at low cost.

In addition, this embodiment can be freely combined with Embodiment Mode or another Embodiment.

### Embodiment 6

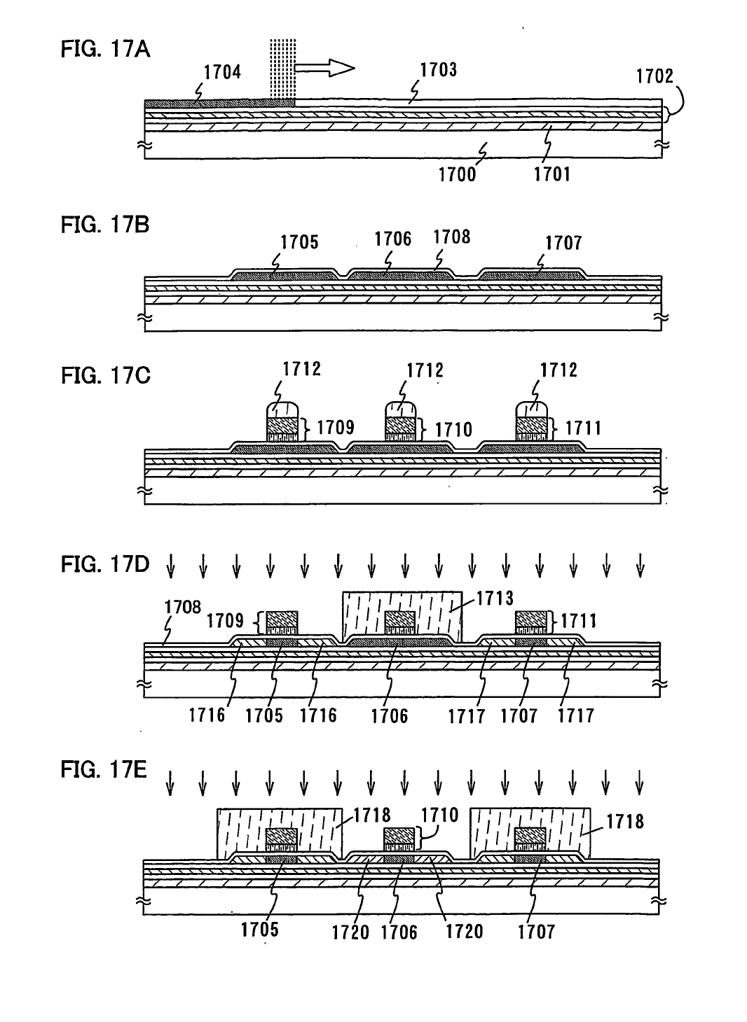

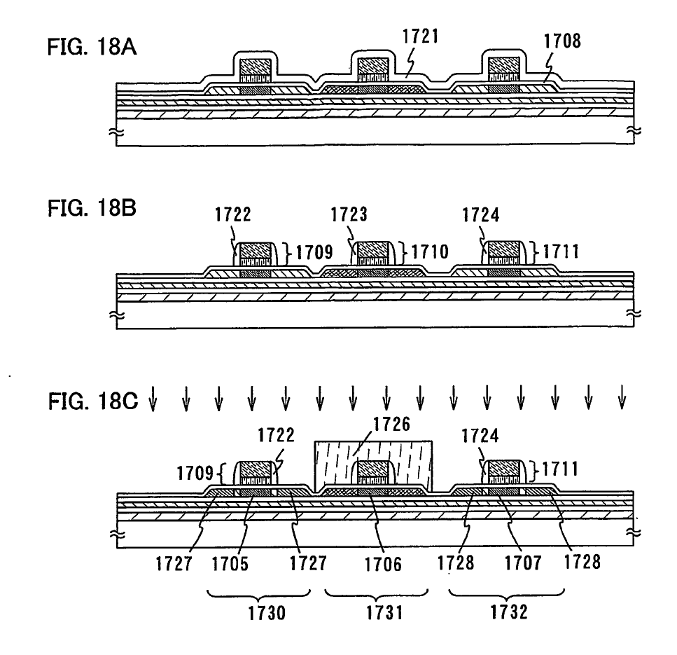

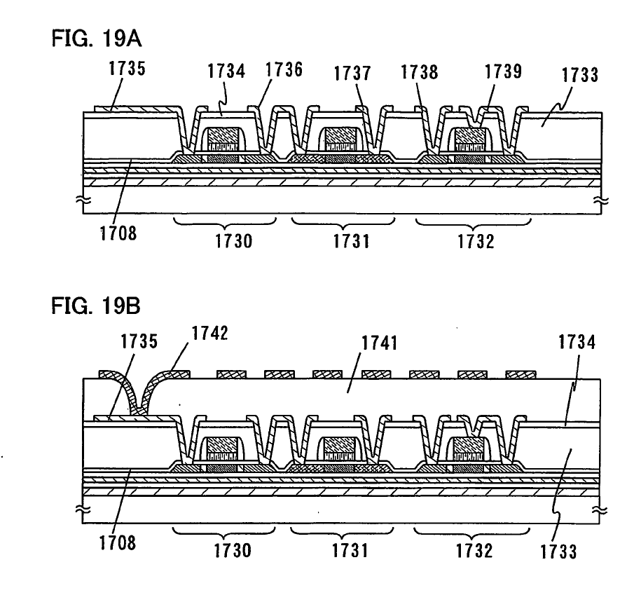

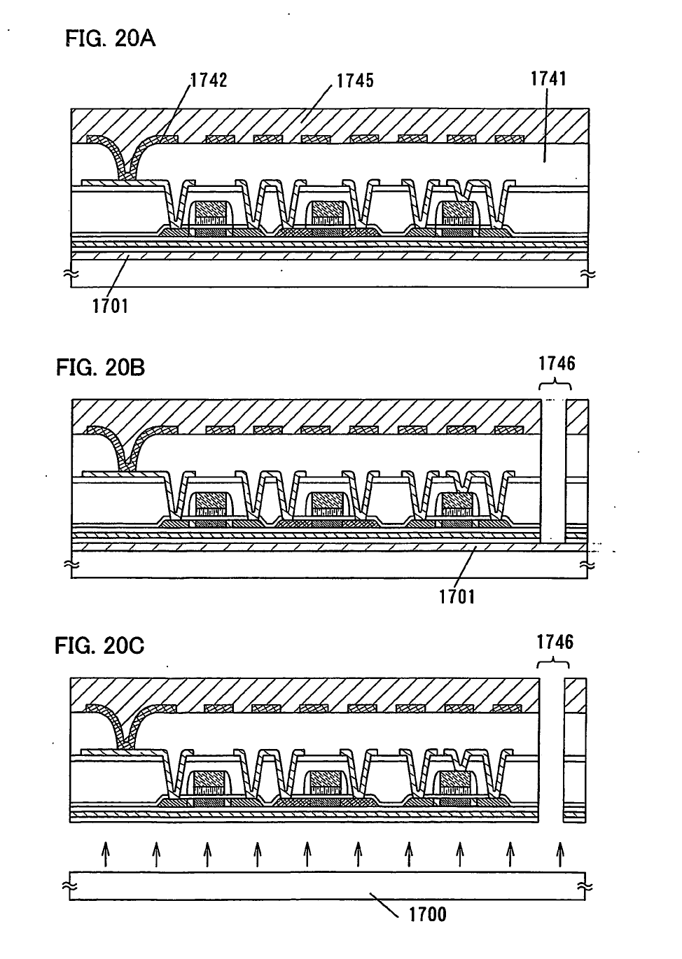

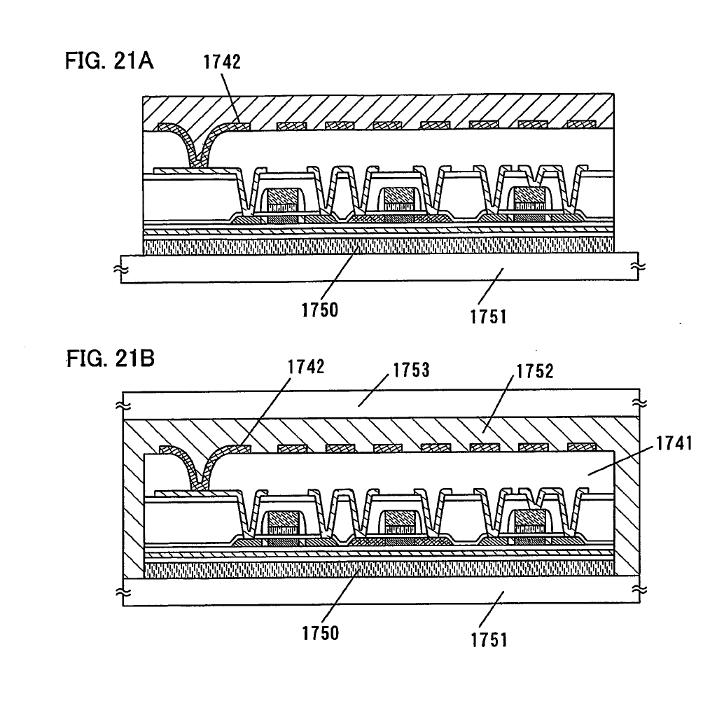

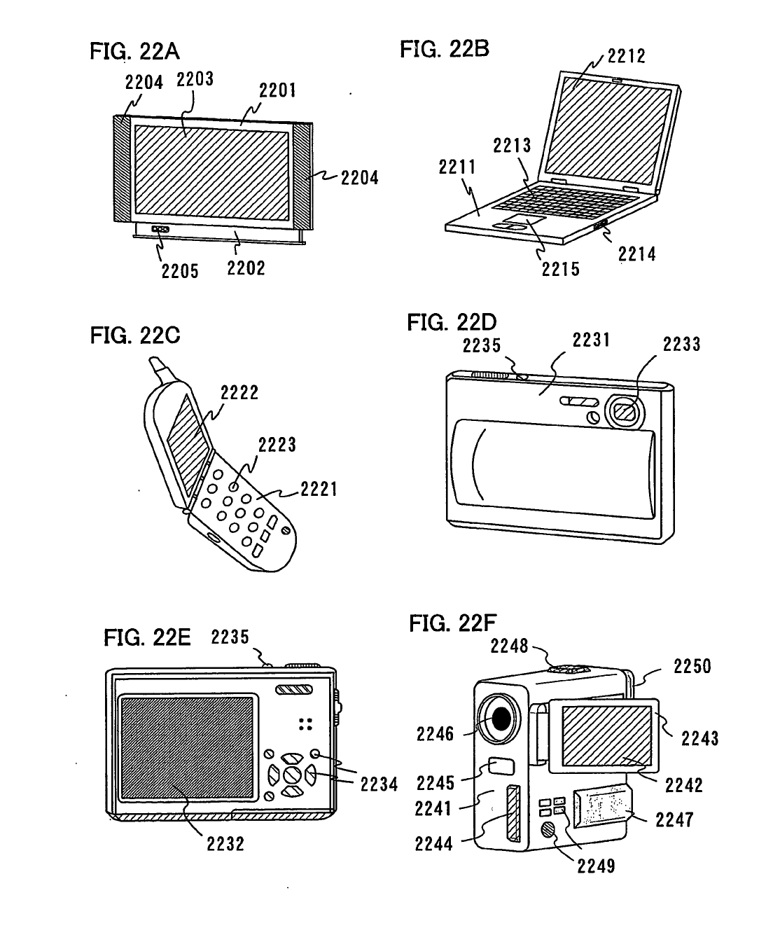

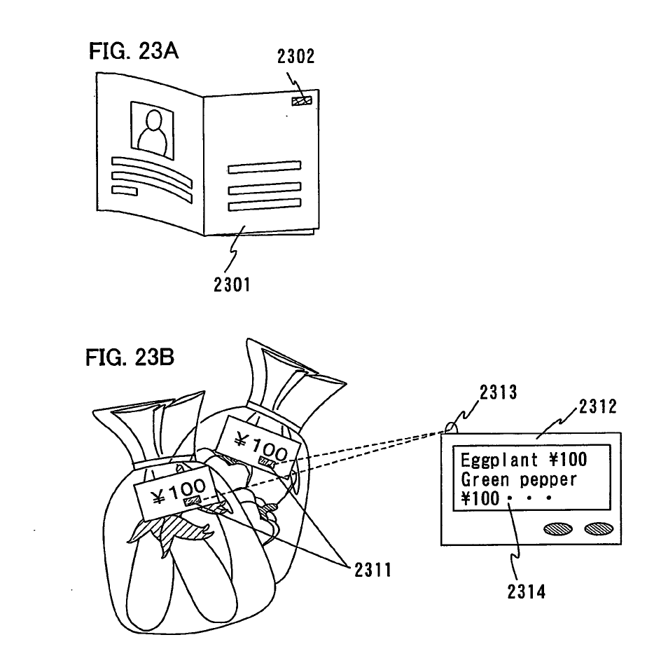

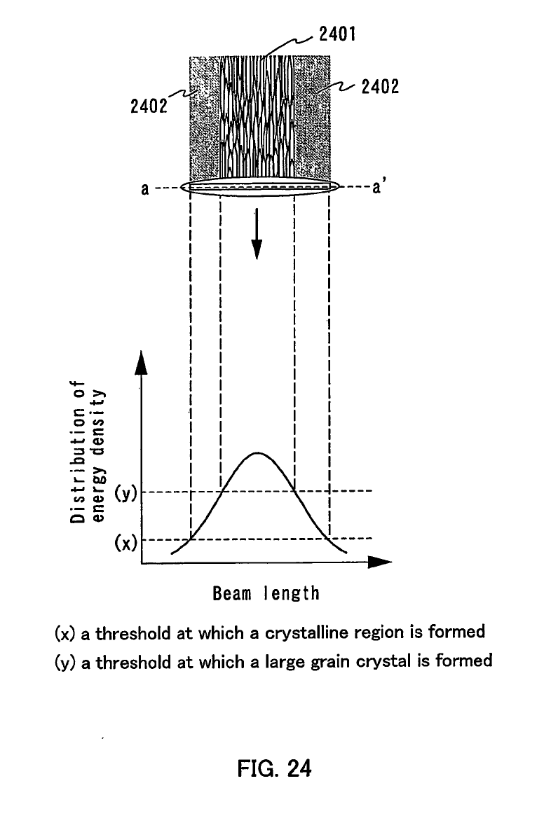

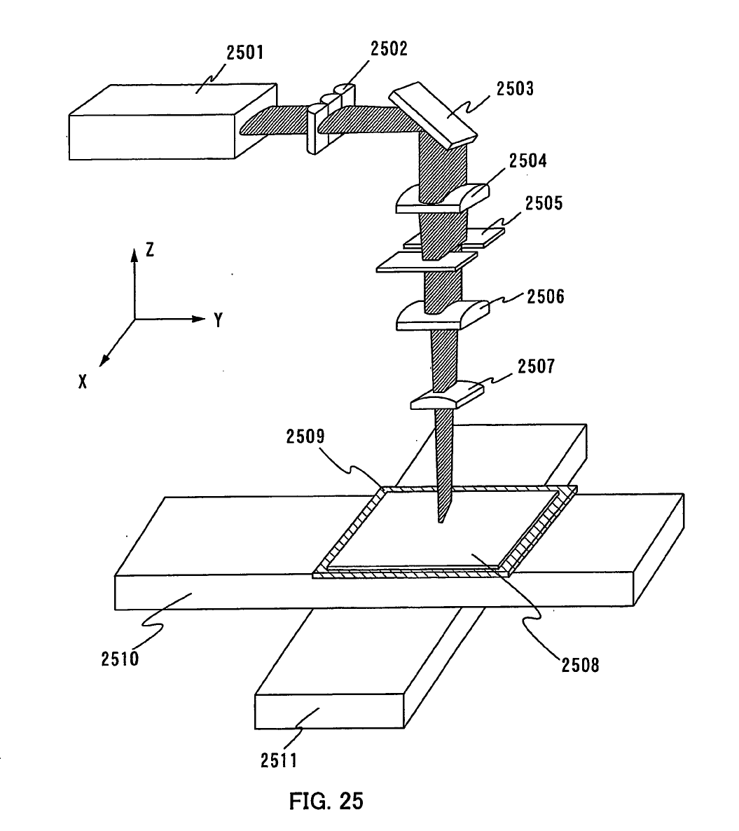

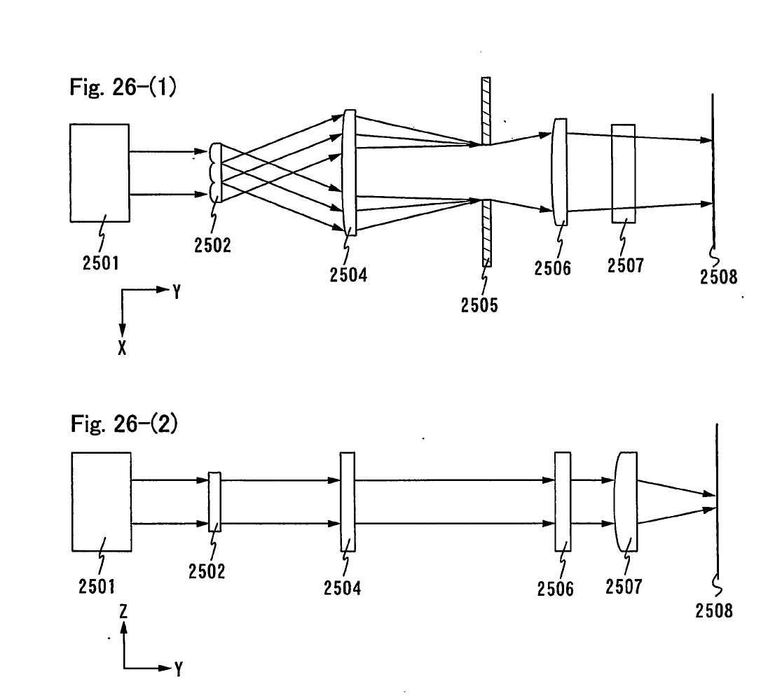

Here, a process of manufacturing a thin film integrated circuit or a contactless thin film integrated circuit device (also referred to as a wireless IC tag or an RFID (Radio Frequency Identification)) as an example of semiconductor devices manufactured by the present invention, with reference to FIGS. 17A to 17E, FIGS. ISA to 18C, FIGS. 19A and 19B, and FIGS. 2OA to 2OC.

Although an example of using electrically-isolated TFTs as semiconductor elements for an integrated circuit of a wireless IC tag is shown below, the semiconductor elements used for the integrated circuit of the wireless IC tag are not limited to TFTs and any kinds of elements can be used. For example, besides TFTs, a storage element, a diode, a photo-electric conversion element, a resistor element, a coil, a capacitor element, an inductor, or the like is typically given.

First, a peeling layer 1701 is formed over a glass substrate (a first substrate) 1700 by a sputtering method as shown in FIG. 17A. The peeling layer 1701 can be formed by a sputtering method, a low-pressure CVD method, a plasma CVD method, or the like. In this embodiment, amorphous silicon is formed in approximately 50 nm thick by a low-pressure CVD method and used as the peeling layer 1701. The film thickness of the peeling layer 1701 desirably ranges from 50 to 60 nm.

The peeling layer 1701 is not limited to silicon and may be formed with a material which can be selectively etched away. For example, the peeling layer 1701 is formed in a single-layer or multilayer structure with an element selected from tungsten (W), molybdenum (Mo), titanium (Ti), tantalum (Ta), niobium (Nb), nickel (Ni), cobalt (Co), zirconium (Zr), zinc (Zn), ruthenium (Rh), rhodium (Rh), palladium (Pd), osmium (Os), and iridium (Ir), or a layer containing an alloy or a compound containing any one of the above elements as its main component. Among the above elements, tungsten can be etched with gas containing halogen fluoride (for example, chlorine trifluoride). Tungsten oxide is formed by irradiating tungsten with light to oxide the surface of tungsten. This tungsten oxide can be etched more easily than tungsten. The tungsten oxide can be peeled after changing the adhesiveness of the thin films over and under the tungsten oxide film by the irradiation with light.

Next, a base insulating film 1702 is formed over the peeling layer 1701. The base insulating film 1702 is provided in order to prevent alkali-earth metal or alkali metal such as Na included in the first substrate from diffusing into the semiconductor film. Alkali-earth metal and alkali metal have an adverse affect on a characteristic of a semiconductor device when such metals are in the semiconductor. Moreover, the base insulating film 1702 serves to protect semiconductor elements in a later step of peeling the semiconductor elements. The base insulating film 1702 may have a single-layer structure or a multilayer structure including a plurality of insulating films. Therefore, the base insulating film 1702 is formed with an insulating material which can suppress the diffusion of alkali metal or alkali-earth metal into the semiconductor film, such as silicon oxide, silicon nitride, silicon oxide containing nitrogen (SiON), or silicon nitride containing oxygen (SiNO).

Next, an amorphous semiconductor film 1703 is formed over the base insulating film 1702. It is desirable to form the semiconductor film 1703 without being exposed to the air after the base insulating film 1702 is formed. The thickness of the semiconductor film 1703 is set in the range of 20 to 200 nm (desirably 40 to 170 nm, more desirably 50 to 150 nm)

Then, in a similar way to Embodiment Mode and another Embodiment, the semiconductor film 1703 is crystallized by irradiating the semiconductor film 1703 with a laser beam. Thus, a crystalline semiconductor film 1704 is formed. FIG. 17A is a cross-sectional view showing a state in which the laser beam is moved halfway.

Next, a semiconductor film 1707 having a crystal structure is shaped into any form to obtain island-like semiconductor layers 1705 to 1707. After that, a gate insulating film 1708 is formed. The gate insulating film 1708 can be formed with a film containing silicon nitride, silicon oxide, silicon oxide containing nitrogen, or silicon nitride containing oxygen in a single-layer structure or a multilayer structure by a plasma CVD method or a sputtering method.

After forming the gate insulating film 1708, heat treatment may be conducted at 300 to 45O° C. for 1 to 12 hours in an atmosphere containing hydrogen for 3% or more to hydrogenate the island-like semiconductor layers 1705 to 1707. Moreover, plasma hydrogenation (using hydrogen excited in plasma) may be conducted as another means of hydrogenation.

Next, as shown in FIG. 17C, gate electrodes 1709 to 1711 are formed. Here, the gate electrodes 1709 to 1711 are formed by etching Si and W stacked by a sputtering method by using resist 1712 as a mask. The conductive material, structure, and manufacturing method of the gate electrodes 1709 to 1711 are not limited to these and can be appropriately selected. For example, a multilayer structure of NiSi and Si doped with an impurity imparting n-type conductivity or a multilayer structure of TaN (tantalum nitride) and W (tungsten) may be used. Further, a single layer using various conductive materials is also applicable. In the case of forming the gate electrode and an antenna simultaneously, the material may be selected in consideration of those functions.

A mask made of SiOₓ or the like may be used instead of the resist mask. In this case, a step of forming a mask of SiOₓ, SiON, or the like (referred to as a hard mask) by shaping the material into any form is added. However, since the film decrease of the mask at the etching is less than that of the resist, the gate electrodes 1709 to 1711 having a desired width can be formed. Further, the gate electrodes 1709 to 1711 may be formed selectively by a droplet discharging method without using the resist 1712.

Next, as shown in FIG. 15D, the island-like semiconductor film 1706 to be a p-channel TFT is covered with a resist 1713 and the island-like semiconductor layers 1705 and 1707 are doped with an impurity element imparting n-type conductivity (typically P (phosphorus) or Ar (arsenic)) at low concentration by using the gate electrodes 1709 and 1711 as a mask. In this doping step, doping is conducted through the gate insulating film 1708, and a pair of low-concentration impurity regions 1716 and 1717 is formed in the island-like semiconductor layers 1716 and 1717. This doping step may be conducted without covering the island-like semiconductor film 1706 to be the p-channel TFT with the resist.

Subsequently, after removing the resist 1713 by ashing or the like, resist 1718 is newly formed to cover the island-like semiconductor layers 1705 and 1707 to be n-channel TFTs, and then the island-like semiconductor layer 1706 is doped with an impurity element (typically B (boron)) imparting p-type conductivity at high concentration by using the gate electrode 1710 as a mask. In this doping step, the doping is conducted through the gate insulating film 1708 to form a pair of p-type high-concentration impurity regions 1720 in the island-like semiconductor layer 1706.

Subsequently, as shown in FIG. 18A, after removing the resist 1718 by ashing or the like, an insulating film 1721 is formed so as to cover the gate insulating film 1708 and the gate electrodes 1709 to 1711.

After that, the insulating film 1721 and the gate insulating film 1708 are partially etched by an etch back method to form sidewalls 1722 to 1724 to be in contact with side walls of the gate electrodes 1709 to 1712 in a self-aligning manner as shown in FIG. 18B. Mixed gas of CHF₃ and He is used as the etching gas. The step of forming the sidewall is not limited to this.

Then, a resist 1726 is newly formed to cover the island-like semiconductor layer 1706 to be the p-channel TFT and an impurity element imparting n-type conductivity (typically P or As) is added at high concentration by using the gate electrodes 1709 and 1711 and the sidewalls 1722 and 1724 as a mask as shown in FIG. 18C. In this doping step, doping is conducted through the gate insulating film 1708 and a pair of high-concentration impurity regions 1727 and 1728 is formed in the island-like semiconductor layers 1705 and 1707.

Next, after the resist 1726 is removed by ashing or the like, the impurity regions may be thermally activated. For example, after forming a 50-nm-thick SiON film, heat treatment may be conducted at 550° C. for four hours in a nitrogen atmosphere. Moreover, when another heat treatment is conducted at 41O° C. for one hour in a nitrogen atmosphere after forming a 100-nm-thick SiNₓ film containing hydrogen, a defect in a poly-crystalline semiconductor film can be improved. This is, for example, to terminate a dangling bond in the poly-crystalline semiconductor film and referred to as a hydrogenation step or the like.

By the above steps, an n-channel TFT 1730, a p-channel TFT 1731, and an n-channel TFT 1732 are formed. In the above manufacturing steps, a TFT having a channel length of 0.2 to 2 μm can be formed by appropriately changing a condition of an etch back method to adjust the size of the sidewall.

Moreover, a passivation film may be formed to protect the TFTs 1730 to 1732.

Subsequently, a first interlayer insulating film 1733 is formed so as to cover the TFTs 1730 to 1732 as shown in FIG. 19A.

Moreover, a second interlayer insulating film 1734 is formed over the first interlayer insulating film 1733. A filler may be mixed into the first interlayer insulating film 1733 or the second interlayer insulating film 1734 in order to prevent the first interlayer insulating film 1733 and the second interlayer insulating film 1734 from peeling and breaking due to the stress caused by the difference of the coefficient of thermal expansion between the conductive material for constituting the wiring to be formed afterward and the first interlayer insulating film 1733 or the second interlayer insulating film 1734.

Next, as shown in FIG. 19A, contact holes are formed in the first interlayer insulating film 1733, the second interlayer insulating film 1734, and the gate insulating film 1708, and then wirings 1735 to 1739 to connect with the TFTs 1730 to 1732 are formed. It is noted that the wirings 1735 and 1736 are connected to the high-concentration impurity region 1727 of the n-channel TFT 1730, the wirings 1736 and 1737 are connected to the high-concentration impurity region 1720 of the p-channel TFT 1731, and the wirings 1738 and 1739 are connected to the high-concentration impurity region 1728 of the n-channel TFT 1732. The wiring 1739 is also connected to the gate electrode 1711 of the n-channel TFT 1732. The n-channel TFT 1732 can be used as a memory element of a random ROM.

Next, as shown in FIG. 19B, a third interlayer insulating film 1741 is formed over the second interlayer insulating film 1734 so as to cover the wirings 1735 to 1739. The third interlayer insulating film 1741 is formed in such a way that the opening portion is formed at a position where the wiring 1735 is partially exposed. The third interlayer insulating film 1741 can be formed with the same material as the first interlayer insulating film 1733.

Next, an antenna 1742 is formed over the third interlayer insulating film 1741. The antenna 1742 can be formed with a conductive material having one or a plurality of metals or metal compounds each of which contains Ag, Au, Cu, Pd, Cr, Mo, Ti, Ta, W, Al, Fe, Co, Zn, Sn, or Ni. The antenna 1742 is connected to the wiring 1735. Although the antenna 1742 is directly connected to the wiring 1735 in FIG. 19B, the wireless IC tag of the present invention is not limited to this structure. For example, the antenna 1742 may be connected electrically to the wiring 1735 by using a wiring separately formed.

The antenna 1742 can be formed by a printing method, a photolithography method, an evaporation method, a droplet-discharging method, or the like. In this embodiment, the antenna 1742 is formed with a single conductive film. However, the antenna 1742 can be formed by stacking a plurality of conductive films. For example, the antenna 1742 may be formed with Ni wiring coated with Cu by electroless plating.

A droplet-discharging method is a method for forming a predetermined pattern by discharging a droplet including a predetermined composition from a small hole. An ink-jet method and the like are included in its category. On the other hand, a printing method includes a screen printing method, an offset printing method, and the like. When a printing method or a droplet-discharging method is employed, the antenna 1742 can be formed without using a mask for light exposure. Moreover, when a printing method or a droplet-discharging method is employed, unlike a photolithography method, the material that will be etched away can be saved. Moreover, since an expensive mask for the light exposure is not necessary, the cost for manufacturing the ID chip can be reduced.

In the case of using a droplet-discharging method or various kinds of printing methods, for example, a conductive particle of Cu coated with Ag can be used. When the antenna 1742 is formed by a droplet-discharging method, it is desirable to perform a process for improving the adhesiveness of the antenna 1742 to a surface of the third interlayer insulating film 1741.

There are several methods to improve the adhesiveness. One is that a metal or a metal compound that can improve the adhesiveness of a conductive film or an insulating film due to a catalytic action is attached to the surface of the third interlayer insulting film 1741. Another is that an organic insulating film, a metal, or a metal compound having high adhesiveness to a conductive film or an insulating film to be formed is attached to the surface of the third interlayer insulating film 1741. Another is that a plasma process is performed to the surface of the third interlayer insulating film 1741 under atmospheric pressure or reduced pressure so that the surface thereof is modified.

When the metal or the metal compound attached to the third interlayer insulating film 1741 is conductive, the sheet resistance is controlled so that the normal operation of the antenna is not interrupted. Specifically, the average thickness of the conductive metal or metal compound may be in the range of 1 to 10 nm. Moreover, the metal or the metal compound may be insulated partially or wholly by oxidization. Furthermore, the metal or the metal compound attached to the region in which the adhesiveness is not necessary may be removed selectively by etching. The metal or the metal compound may be attached selectively only to a particular region by a droplet-discharging method, a printing method, or a sol-gel method instead of etching the metal or the metal compound after attaching the metal or the metal compound all over the substrate. The metal or the metal compound does not need to be a totally continuous film over the surface of the third interlayer insulating film 1741 but may be dispersed to some extent.

Then, as shown in FIG. 2OA, after forming the antenna 1742, a protective layer 1745 is formed over the third interlayer insulating film 1741 so as to cover the antenna 1742. The protective layer 1745 is formed with a material which can protect the antenna 1742 when the peeling layer 1701 is etched away afterward. For example, the protective layer 1745 can be formed by applying an epoxy resin, an acrylate resin, or a silicon resin being able to dissolve in water or alcohols all over the surface.

Next, as shown in FIG. 2OB, a groove 1746 is formed in order to divide the wireless IC tags. The groove 1746 may have the depth of such a degree that the peeling layer 1701 is exposed. The groove 1746 can be formed by dicing or scribing the layer. It is noted that the groove 1746 is not necessarily formed when it is not required to divide the wireless IC tags formed over the first substrate 1700.

Next, as shown in FIG. 2OC, the peeling layer 1701 is etched away. In this embodiment, halogen fluoride as an etching gas is introduced from the groove 1746. For example, ClF₃ (chlorine trifluoride) is used under a condition where the temperature is 35O° C., the flow rate is 300 seem, the barometric pressure is 798 Pa, and the process time is 3 hours. Moreover, nitrogen may be mixed into the ClF₃ gas. The peeling layer 1701 can be selectively etched by using halogen fluoride such as ClF₃ so that the TFTs 1730 to 1732 can be peeled from the first substrate 1700. The halogen fluoride may be gas or liquid.

Next, as shown in FIG. 21A, the peeled TFTs 1730 to 1732 and the antenna 1742 are pasted to a second substrate 1751 by using an adhesive agent 1750. The adhesive agent 1750 is formed with a material that can paste the second substrate 1751 and the base film 1702. The adhesive agent 1750 may be, for example, a reactive-curing type, a thermal-curing type, a photo-curing type such as a UV-curing type, or an anaerobic type.

The second substrate 1751 can be formed with a flexible organic material such as paper or plastic.

As shown in FIG. 21B, after removing the protective layer 1745, an adhesive agent 1752 is applied onto the third interlayer insulating film 1741 so as to cover the antenna 1742, and then a cover member 1753 is pasted. As the cover member 1753, a flexible organic material such as paper or plastic can be used like the second substrate 1751. For example, the thickness of the adhesive agent 1752 may range from 10 to 200 μm.

The adhesive agent 1752 is formed with a material being able to paste the cover member 1753 to the third interlayer insulating film 1741 and the antenna 1742. The adhesive agent 1752 may be, for example, a reactive-curing type, a thermal-curing type, a photo-curing type such as a UV-curing type, or an anaerobic type.

According to the above-mentioned steps, the wireless IC tag is completed. Through the above manufacturing method, an extremely thin integrated circuit having the total thickness in the range of 0.3 to 3 μm, typically about 2 μm, can be formed between the second substrate 1751 and the cover member 1753.

The thickness of the integrated circuit includes not only the thickness of the semiconductor element itself but also the thicknesses of the insulating films and the interlayer insulating films formed between the adhesive agent 1750 and the adhesive agent 1752. The integrated circuit in the wireless IC tag can be made to have a length of 5 mm or less on a side (25 mm² or less), more preferably in the range of approximately 0.3 mm (0.09 mm²) to 4 mm (16 mm²) on a side.

This embodiment has described the method in which the peeling layer is provided between the first substrate 1700 having high heat resistance and the integrated circuit, and the substrate and the integrated circuit are separated by removing the peeling layer through the etching. However, a method for manufacturing the wireless IC tag of the present invention is not limited to this structure. For example, a metal oxide film may be provided between the integrated circuit and the substrate having high heat resistance, and the metal oxide film may be weakened by crystallization so that the integrated circuit is peeled. Alternatively, the peeling layer formed with an amorphous semiconductor film containing hydrogen may be provided between the integrated circuit and the substrate having high heat resistance, and the peeling layer may be removed by the laser irradiation. Alternatively, the integrated circuit may be peeled from the substrate by mechanically removing the substrate having high heat resistance with the integrated circuit formed thereover or by etching the substrate away using solution or gas.

Although this embodiment has described the example for forming the antenna over the same substrate as the integrated circuit, the present invention is not limited to this structure. The antenna and the integrated circuit formed over different substrates may be pasted afterward so that they are connected electrically.

The frequency of an electric wave usually applied in RFID (Radio Frequency Identification) is 13.56 MHz or 2.45 GHz, and it is important to form the wireless IC tag so that the electric waves of these frequencies can be detected in order to enhance the versatility.

The wireless IC tag of this embodiment has advantages that the electric wave is hard to be blocked compared to an RFID formed using a semiconductor substrate and that attenuation of a signal due to the block of the electric wave can be suppressed. Since a semiconductor substrate is not necessary in the present invention, the cost for manufacturing the wireless IC tag can be reduced drastically.

Although this embodiment has described the example in which the peeled integrated circuit is pasted to the flexible substrate, the present invention is not limited to this. For example, if the substrate can resist the heat process in the manufacturing steps of the integrated circuit like a glass substrate, the integrated circuit over the glass substrate is not necessarily peeled.

This embodiment can be freely combined with Embodiment Mode or another Embodiment.

### Embodiment 7

With the semiconductor material to which the laser irradiation has been conducted by applying the present invention, various electronic appliances can be completed. For example, a camera such as a video camera or a digital camera, a goggle type display (a head mount display), a navigation system, a sound reproduction device (an audio component), a TV (a display), a mobile terminal, or the like is given. By employing the present invention, the whole surface of the substrate can be annealed favorably, which makes it possible to increase the degree of freedom in the layout and size of a semiconductor element and to increase the degree of integration of semiconductor elements. Since the degree of crystallization is the same in any part of the substrate, the product quality of the manufactured semiconductor element is favorable and the variation in the product quality can be prevented. As a result, an electronic appliance as a final product can be manufactured with high throughput and high quality. Specific examples are described with reference to the drawings.

FIG. 22A shows a display device including a case 2201, a supporting stand 2202, a display portion 2203, speaker portions 2204, a video input terminal 2205, and the like. This display device is manufactured by using a thin film transistor formed by the manufacturing method shown in another embodiment in the display portion 2203. By using the semiconductor material to which the laser irradiation has been conducted according to the present invention, it is possible to increase the area of the large grain region and decrease the area of the inferior crystalline region without causing an interference pattern of a laser to appear on the semiconductor film. Further, by annealing with a longer beam according to the present invention, a larger display device can be manufactured. The display device includes a liquid crystal display device, a light-emitting device, and the like, and specifically includes all the display devices for displaying information for a computer, television reception, advertisement, and so on.

FIG. 22B shows a computer including a case 2211, a display portion 2212, a keyboard 2213, an external connection port 2214, a pointing mouse 2215, and the like. The manufacturing method shown in another embodiment can be applied to the display portion 2212 and other circuits. Moreover, the present invention can be applied to a semiconductor device inside a main body such as a CPU or a memory.

FIG. 22C shows a mobile phone as a typical example of mobile terminals. This mobile phone includes a case 2221, a display portion 2222, operation keys 2223, and the like. When the semiconductor material to which the laser irradiation has been conducted according to the present invention is used in an electronic appliance such as a mobile phone, a PDA (personal digital assistant), a digital camera, or a compact game machine, the quality of the display portion 2222 and functional circuits such as a CPU and a memory is favorable and the variation in the quality can be prevented.

FIGS. 22D and 22E show a digital camera. It is noted that FIG. 22E shows a rear side of FIG. 22D. This digital camera includes a case 2231, a display portion 2232, a lens 2233, operation keys 2234, a shutter 2235, and the like. By using a semiconductor material to which laser irradiation has been conducted according to the present invention, the quality of the display portion 2233, a driver portion for controlling the display portion 2233, and other circuits are favorable, and the variation in the quality can be suppressed.

FIG. 22F shows a digital video camera including a main body 2241, a display portion 2242, a case 2243, an external connection port 2244, a remote control receiving portion 2245, an image receiving portion 2246, a battery 2247, an audio input portion 2248, operation keys 2249, an eyepiece portion 2250, and the like. By using a semiconductor material to which laser irradiation has been conducted according to the present invention, the quality of the display portion 2242, a driver portion for controlling the display portion 2242, and other circuits are favorable, and the variation in the quality can be suppressed.

ATFT manufactured by using a laser irradiation apparatus of the present invention can be used for a thin film integrated circuit or a contactless thin film integrated circuit device (also referred to as a wireless IC tag or an RFID (Radio Frequency Identification)). By applying the manufacturing method shown in another embodiment, the thin film integrated circuit and the contactless thin film integrated circuit can be used as a tag or a memory.

FIG. 23A shows a passport 2301 to which a wireless IC tag 2302 is attached. The wireless IC tag 2302 may be embedded in the passport 2301. In the same way, the wireless IC tag may be attached to or embedded in a driver's license, a credit card, a banknote, a coin, a certificate, a merchandise coupon, a ticket, a traveler's check (T/C), a health insurance card, a residence certificate, a family register, or the like. In this case, only the information showing that this product is a real one is inputted into the wireless IC tag, and access authority is set so that the information is not read out or written in illegally. This can be achieved by using the memory shown in another embodiment. Thus, by using as the tag, real products can be distinguished from forged ones.

Besides, the wireless IC tag can also be used as a memory. FIG. 23B shows an example of using the wireless IC tag 2311 embedded in a label which is attached to a package of vegetables. The wireless IC tag 2311 may be attached to or embedded in the package itself. In the wireless IC tag 2311, a production area, a producer, a manufacturing date, a process at the production such as a process method, a circulation process of a product, a price, quantity, an intended purpose, a shape, weight, an expiry date, or other identification information can be stored. The information from the wireless IC tag 2311 can be received by an antenna portion 2313 of a wireless reader 2312, and read out and displayed in a display portion 2314 of the reader 2312. Thus, wholesalers, retailers, and consumers can know such information easily. Further, by setting the access authority for each of the producers, the traders, and the consumers, those who do not own the access authority cannot read, write, rewrite, and erase the information.

The wireless IC tag can be used as follows. At the settlement, the information that the settlement has been made is written in the wireless IC tag, and the wireless IC tag is checked by a checking means provided at an exit whether or not the information that the settlement has been made is written in the wireless IC tag. If the IC tag is brought out from the store without making the settlement, the alarm rings. With this method, forgetting of the settlement and shoplifting can be prevented.

In consideration of protecting customer's privacy, the following method is also possible. At the settlement at a cash register, any of the followings is conducted; (1) data inputted in the wireless IC tag are locked by pin numbers or the like, (2) data itself inputted in the wireless IC tag are encrypted, (3) data inputted in the wireless IC tag are erased, and (4) data inputted in the wireless IC tag are destroyed. These can be achieved by using the memory described in another embodiment. Then, a checking means is provided at an exit, and whether any one of (1) to (4) has been conducted or whether the data in the wireless IC tag are not processed is checked so that whether the settlement has been made or not is checked. In this way, whether the settlement has been made or not can be checked in the store, and reading out the information in the wireless IC tag against the owner's will outside the store can be prevented.

Several methods are given to destroy the data inputted in the wireless IC tag of (4). For example, the followings are given: (a) a method in which only the data are destroyed by writing one or both of “0” (off) and “1” (on) in at least a portion of the electronic data in the wireless IC tag and (b) a method in which an excessive amount of current is flowed through the wireless IC tag to physically destroy a part of a wiring of a semiconductor element in the wireless IC tag.

Since the wireless tags mentioned above require higher manufacturing cost than conventionally used barcodes, the cost reduction is necessary. According to the present invention, however, high-quality semiconductor elements having no variation can be formed with high throughput, which is effective for the cost reduction. The wireless tags can be manufactured with high quality so as to have no variation of performance.

As thus described, the semiconductor device manufactured by the present invention can be applied to a wide range, and the semiconductor device manufactured by the present invention can be applied to electronic appliances of every field.

### Embodiment 8

This embodiment will describe another structure of a laser irradiation apparatus used in the present invention, with reference to FIG. 25 and FIGS. 26-(1) and 26-(2). In this embodiment, a slit is provided in addition to the structure used in Embodiment Mode of the present invention. An end portion of a laser beam is blocked by this slit, and an image formed by the slit is projected to an irradiation surface by a projecting lens. Further, similarly, a slit and a projecting lens can be combined with the structure of Embodiment 1.

In this embodiment, a laser beam emitted from a mode-locked pulsed laser oscillator 2501 oscillating multiple wavelengths with a repetition rate of 10 MHz or more is shaped into a linear beam through an optical system and delivered to a substrate 2509 with a semiconductor film 2508 formed thereover.

A top view of FIG. 26-(1) is described first. In this embodiment, a laser oscillator using a Ti:sapphire crystal as a laser crystal is used as the laser oscillator 2501. The central wavelength of the fundamental wave emitted from this laser is 800 nm, and a full width at half maximum of the oscillation wavelength is 30 nm. This fundamental wavelength is converted into a second harmonic by a non-linear optical crystal inside the laser oscillator 2501. The central wavelength of this second harmonic is 400 nm, and a full width at half maximum thereof is 15 nm.

Not only the laser beam mentioned here but also a laser beam emitted with a wide range of wavelengths with respect to the excitation light source can be used. For example, a laser oscillator using ceramic YAG doped with a plurality of dopants such as Nd and Yb can be used.

Next, the emitted laser beam enters a cylindrical lens array 2502. The laser beam is divided into a plurality of laser beams in an X-axis direction by the cylindrical lens array 2502 and the plurality of laser beams are combined so that the intensity of the laser beam is homogenized. In this embodiment, the X-axis direction indicates a major-axis direction of the laser beam.

Although the laser beam is divided into three beams and the three laser beams are combined into one beam in this embodiment, the difference in the intensity of the laser beam due to the interference can be offset by using such a laser beam because the interval of the interference pattern is different with respect to each wavelength as can be seen from the formula (1) described above. Since this can decrease the effect of the interference, the intensity distribution of the laser beam in the direction of the length of the linear beam can be homogenized, and moreover, the inferior crystalline region can be decreased.

Next, the laser beam is condensed in a Z-axis direction by a cylindrical lens 2504 acting only in the X-axis direction and enters a slit 2505 for blocking an end portion of the laser beam in the X-axis direction.

The portion of the laser beam that has low intensity can be blocked by the slit 2505; however, diffracted light is generated at the same time. When this diffracted light is delivered to the semiconductor film 2508, an interference pattern appears on the semiconductor film 2508 and it becomes difficult to crystallize the whole surface of the semiconductor film 2508 homogeneously. Consequently, a projecting lens 2506 is provided so that the slit 2505 and the semiconductor film 2508 are conjugated planes, and then an image at the slit 2505 is projected to the semiconductor film 2508. In this embodiment, a convex cylindrical lens is used as the projecting lens 2506.

Next, a side view of FIG. 26B is described. The laser beam emitted from the laser oscillator 2501 sequentially enters the cylindrical lens array 2502 and the cylindrical lens 2504. However, since the cylindrical lens array 2502 and the cylindrical lens 2504 do not act in the X-axis direction of the laser beam, the laser beam passes therethrough without any changes. Sequentially, the laser beam enters the projecting lens 2506; however, since the projecting lens 2506 also does not act in the X-axis reaction of the laser beam, the laser beam passes therethrough without any changes. After the laser beam passes through the projecting lens 2506, the laser beam is condensed in the Z-axis direction by a cylindrical lens 2507 and then delivered to the semiconductor film 2508. In this embodiment, the Z-axis direction is a minor-axis direction of the laser beam.

In fact, the laser beam after passing through the cylindrical lens array 2502 shown in FIG. 25 is deflected by a mirror 2503 and delivered to the semiconductor film 2508. The position and number of mirrors 2503 are not limited to those shown in FIG. 25 and can be appropriately determined as necessary.

The substrate 2509 with the semiconductor film 2508 formed is made of glass and fixed onto a suction stage so as not to fall during the laser irradiation. The suction stage moves repeatedly in an X direction and a Y direction on a plane parallel to a surface of the semiconductor film 2508 with the use of an X stage 2510 and a Y stage 2511, thereby crystallizing the semiconductor film 2508. The X stage 2510 and the Y stage 2511 can be moved at 100 to 1000 mm/s. It is preferable that, at the irradiation of the semiconductor film 2508 with the laser beam, the X stage 2510 or the Y stage 2511 be moved at a constant speed in the minor-axis direction of the laser beam. The speed is particularly preferable in the range of 300 to 500 mm/s.

Although the substrate 2509 with the semiconductor film 2508 formed is moved by using the X stage 2510 and the Y stage 2511 in this embodiment, the laser beam may be moved by any one of the following methods: (1) an irradiation system moving method in which the substrate 2509 as an object is fixed while an irradiation position of the laser beam is moved; (2) an object moving method in which the irradiation position of the laser beam is fixed while the substrate is moved; and (3) a method in which these two methods are combined.

In the region irradiated with the laser beam, a crystal grain grown toward the moving direction of the laser beam is formed. Therefore, this irradiated region has extremely superior crystallinity. By using this irradiated region in a channel forming region of a TFT, extremely high mobility and on current can be expected.

A semiconductor device can be manufactured by manufacturing TFTs by a method shown in another embodiment over the laser-crystallized semiconductor film by such a method and integrating the TFTs.

This embodiment can be freely combined with another Embodiment.

This application is based on Japanese Patent Application serial No. 2004-317057 filed in Japan Patent Office on Oct. 29, 2004, the entire contents of which are hereby incorporated by reference.

1. A laser irradiation method comprising:
changing a first laser beam emitted from a solid-state laser oscillator which oscillates a laser beam having a spectral width which is 0.1 nm or more into a second laser beam whose intensity distribution is homogenized by passing through a beam homogenizer;
making the second beam enter an irradiation surface; and
moving the second laser beam relative to the irradiation surface.

2. A laser irradiation method comprising:
changing a first laser beam emitted from a solid-state laser oscillator which oscillates a laser beam having a spectral width which is 0.1 nm or more into a second laser beam whose intensity distribution is homogenized by passing through a beam homogenizer;
changing the second laser beam into a third laser beam by using a condensing lens;
making the third laser beam enter an irradiation surface; and
moving the third laser beam relative to the irradiation surface.

3. A laser irradiation method comprising:
changing a first laser beam emitted from a solid-state laser oscillator which oscillates a laser beam having a spectral width which is 0.1 nm or more into a second laser beam whose intensity distribution is homogenized by passing through a beam homogenizer;
changing the second laser beam into a third laser beam by using a slit to block an end portion of the second laser beam;
making the third laser beam pass through a condensing lens and a projecting lens so that an image of the third laser beam formed by the slit is projected onto an irradiation surface; and
moving the irradiation surface relative to the laser beam.

4. The laser irradiation method according to any one of claims 1 to 3,
wherein the condensing lens is a convex cylindrical lens or a convex spherical lens.

5. The laser irradiation method according to any one of claims 1 to 3,
wherein the solid-state oscillator is a solid-state laser oscillator which includes a crystal of sapphire, YAG, ceramic YAG, ceramic Y₂O₃, KGW, KYW, Mg₂SiO₄, YLF, YVO₄, or GdVO₄ doped with at least one of Nd, Yb, Cr, Ti, Ho and Er.

6. The laser irradiation method according to any one of claims 1 to 3,
wherein the laser beam is converted by a non-linear optical element.

7. The laser irradiation method according to any one of claims 1 to 3,
wherein the beam homogenizer uses any one of a cylindrical lens array, a light pipe, and a fly-eye lens.

8. A digital video camera, a digital camera, a navigation system, a sound reproduction device, a display, a mobile terminal, a thin film integrated circuit device, or a CPU manufactured by using the laser irradiation method according to any one of claims 1 to 3.

9. A laser irradiation apparatus comprising:
a solid-state laser oscillator for oscillating a laser beam having a spectral width which is 0.1 nm or more;
a beam homogenizer for homogenizing intensity distribution of the laser beam emitted from the solid-state laser oscillator; and
means for moving an irradiation surface of the laser beam relative to the laser beam.

10. A laser irradiation apparatus comprising:
a solid-state laser oscillator for oscillating a laser beam having a spectral width which is 0.1 nm or more;
a beam homogenizer for homogenizing intensity distribution of the laser beam emitted from the solid-state laser oscillator;
a condensing lens for condensing the laser beam which has passed through the beam homogenizer; and
means for moving an irradiation surface relative to the laser beam.

11. A laser irradiation apparatus comprising:
a solid-state laser oscillator for oscillating a laser beam having a spectral width which is 0.1 nm or more;
a beam homogenizer for homogenizing intensity distribution of the laser beam emitted from the solid-state laser oscillator;
a slit for blocking an end portion of the laser beam whose intensity distribution has been homogenized by the beam homogenizer;
a condensing lens for condensing the laser beam;
a projecting lens for projecting an image of the laser beam formed by the slit onto an irradiation surface; and
means for moving an irradiation surface relative to the laser beam.

12. The laser irradiation apparatus according to claim 10 or 11,
wherein the condensing lens is a convex cylindrical lens or a convex spherical lens.

13. The laser irradiation apparatus according to any one of claims 9 to 11,
wherein the solid-state laser oscillator is a solid-state laser oscillator which includes a crystal of sapphire, YAG, ceramic YAG, ceramic Y₂O₃, KGW, KYW, Mg₂SiO₄, YLF, YVO₄, or GdVO₄ doped with at least one of Nd, Yb, Cr, Ti, Ho and Er.

14. The laser irradiation apparatus according to any one of claims 9 to 11,
wherein the laser beam is a harmonic converted by a non-linear optical element.

15. The laser irradiation apparatus according to any of claims 9 to 11,
wherein the beam homogenizer is any one of a cylindrical lens array, a light pipe, and a fly-eye lens.

16. A digital video camera, a digital camera, a navigation system, a sound reproduction device, a display, a mobile terminal, a thin film integrated circuit device, or a CPU manufactured by using the laser irradiation apparatus according to any one of claims 9 to 11.
